(19) United States
(12) Patent Application Publication
(10) Pub. No.: US 2022/0254998 A1
(43) Pub. Date: Aug. 11, 2022

(54) CONDUCTIVE BRIDGE MEMORY DEVICE, MANUFACTURING METHOD THEREOF, AND SWITCHING DEVICE

(71) Applicants: NATIONAL UNIVERSITY CORPORATION TOTTORI UNIVERSITY, Tottori-shi, Tottori (JP); NATIONAL INSTITUTE OF ADVANCED INDUSTRIAL SCIENCE AND TECHNOLOGY, Tokyo (JP); NAGASE & CO., LTD., Osaka-shi, Osaka (JP)

(72) Inventors: Toshiyuki ITOH, Tottori-shi (JP); Toshiki NOKAMI, Tottori-shi (JP); Kentaro KINOSHITA, Tokyo (JP); Hisashi SHIMA, Tsukuba-shi (JP); Yasuhisa NAITOH, Tsukuba-shi (JP); Hiroyuki AKINAGA, Tsukuba-shi (JP); Hiroshi SATOU, Tsukuba-shi (JP); Shigeki MORII, Tokyo (JP); Kusuo OTA, Tokyo (JP); Atsushi TANAKA, Tokyo (JP)

(73) Assignees: NATIONAL UNIVERSITY CORPORATION TOTTORI UNIVERSITY, Tottori-shi, Tottori (JP); NATIONAL INSTITUTE OF ADVANCED INDUSTRIAL SCIENCE AND TECHNOLOGY, Tokyo (JP); NAGASE & CO., LTD., Osaka-shi, Osaka (JP)

(21) Appl. No.: 17/639,201

(22) PCT Filed: Aug. 28, 2020
(86) PCT No.: PCT/JP2020/032668

§ 371 Date: Feb. 28, 2022

(30) Foreign Application Priority Data
Aug. 30, 2019 (JP) 2019-158101
Feb. 19, 2020 (JP) 2020-026379

(51) Int. Cl. H01L 45/00

(52) U.S. Cl. CPC H01L 45/1246; H01L 45/1608; H01L 45/1253; H01L 45/085

(57) ABSTRACT

A conductive bridge memory device includes a memory cell including a first metal layer; a second metal layer; a first insulator layer having a first surface facing the first metal layer and a second surface facing the second metal layer and being a surface opposite to the first surface, and having a through hole penetrating between the first surface and the second surface; and a liquid layer being formed of liquid containing a liquid electrolyte impregnated in the through hole.

### TECHNICAL FIELD

The present disclosure relates to a conductive bridge memory device and a manufacturing method thereof, and a switching device.

### BACKGROUND ART

CB-RAM (Conducting bridge random access memory) or an atom switch has a simple structure of electrode A/solid electrolyte (memory layer)/electrode B, in which structure a solid electrolyte material is sandwiched by an electrode A composed of an electrochemically active metal (for example, Ag, Cu) and an electrode B composed of an inactive metal (for example, Pt). Applying a positive voltage to the electrode A (with respect to the electrode B) causes atoms constituting the electrode A to be ionized to penetrate into the solid electrolyte and move toward the electrode B. The metal ions reaching the electrode B receive electrons to be precipitated as a metal. As a result, a filament-like conductive path formed of the metal constituting the electrode A is formed inside the solid electrolyte, and the electrode A and the electrode B being connected causes the low resistance state to be realized. On the other hand, applying a negative voltage to the electrode A (with respect to the electrode B) causes atoms constituting the electrode A constituting the filament to be ionized. The orientation of the electric field is reverse the orientation at the time of forming the filament, so that atoms constituting the filament are recovered by the electrode A, causing the high resistance state to be restored. In other words, the CB-RAM being made possible to replace the resistance value change by a signal of “1” and “0” and functioning as a memory has excellent features such as high speed, high integration, and low power consumption, so that the above-mentioned element is expected as a replacement for a flash memory, which will face the minituarization limit in the near future, and further as a universal memory having both high speed and non-volatility. The high resistance state of the CB-RAM can be assumed to be the “OFF” state since current is difficult to flow, while the low resistance state thereof can be assumed to be the “ON” state since current easily flows. Thus, the CB-RAM can be used not only as a memory element but also as a switch, it is superior in the current transport characteristic since the conductive path is composed of a metal, the possibility thereof for an atom transistor is expected, and the application thereof for a circuit changeover switch for FPGA (field programmable gate array) is also expected.

The inventors have revealed that design of a stable and high-performance CB-RAM is made possible by impregnating an ionic liquid in a porous body layer (see Patent document 1, Non-patent documents 1, 2, 3, 4, 5). FIG. 1A is a schematic view showing a cross section of the Cu/porous body (HfO₂ (hafnia) in FIG. 1A)/Pt structure. While not shown here, pores whose position, size, shape, and density are random are formed in the porous body layer, and an ionic liquid is filled into the above-mentioned pores. As shown in FIG. 1A, the Pt electrode is grounded, while a voltage is applied to the Cu electrode. A bipolar operation (see FIG. 1B) of a positive bias applied to the Cu electrode causing set (resistive switching from high resistance to low resistance) and a negative bias applied thereto causing reset (resistive switching from low resistance to high resistance) was confirmed. The function in which the CB-RAM repeats the set-reset resistive switching is exhibited via a filament forming process called forming. While the current-voltage characteristic for the forming is similar to that for the set, a forming voltage (V_{form}) being the voltage at which forming occurs is generally higher than a voltage at which set occurs (Vₛₑₜ).

In a case that an ionic liquid is impregnated in an HfO₂ layer of a Cu/HfO₂/Pt cell, stabilization of the HfO₂ layer in the switching operation improves markedly, and adding therein an ionic liquid containing 5000 ppm of moisture resulted in a salient stabilization that destruction of HfO₂ element does not occur at all even when a voltage of greater than or equal to 10V is applied thereto (Non-patent documents 1, 2). Then, they have studied the design of an ionic liquid to be added and have revealed that an ionic liquid having a high ionic conductivity and having an anion having a low proton acceptability can decrease the set voltage (Vₛₑₜ) and the reset voltage (Vᵣₑₛₑₜ) (see Non-patent document 3).

The resistance value change of a CB-RAM is caused by a metal filament formed in pores in a porous body layer. Therefore, in a CB-RAM in which a porous body layer is sandwiched by a Cu foil and a Pt substrate, a copper filament made by electrodeposition in the porous body layer is the primary cause for bringing about the resistance value change. Then, it was found that the switching endurance improved remarkably when an ionic liquid being made to contain Cu²⁺ ions in advance was added to the HfO₂ layer (see Non-patent documents 2, 3, 4). It was found that Vₛₑₜ, Vᵣₑₛₑₜ increased slightly. It was found that, when a solvated ionic liquid was impregnated in the HfO₂ layer to solve this problem, Vₛₑₜ, Vᵣₑₛₑₜ decreased even though the solvated ionic liquid used was extremely high in viscosity and, even more, the switching endurance greatly improved (see Non-patent document 5).

### PRIOR ART DOCUMENTS

### Patent Document

Patent Document 1: JP 6195155 B

### Non-Patent Documents

Non-patent document 1: Harada, A.; Yamaoka, H.; Ogata, R.; Watanabe, K.; Kinoshita, K.; Kishida, S.; Nokami, T.; Itoh, T. J. Mater. Chem. C, 2015, 3, 6966-6969.
Non-patent document 2: Harada, A.; Yamaoka, H.; Watanabe, K.; Kinoshita, K.; Kishida, S.; Fukaya, Y.; Nokami, T.; Itoh, T.Chem. Lett., 2015, 44, 1578-1580.
Non-patent document 3: Harada, A.; Yamaoka, H.; Tojo, S.; Watanabe, K.; Sakaguchi, A.; Kinoshita, K.; Kishida, S.; Fukaya, Y.; Matsumoto, K.; Hagiwara, R.; Sakaguchi, H.; Nokami, T.; Itoh, T. J. Mater. Chem. C, 2016, 4, 7215-7222
Non-patent document 4: Kinoshita, K.; Sakaguchi, A.; Harada, A.; Yamaoka, H.; Kishida, S.; Fukaya, Y.; Nokami, T.; Itoh, T. Jpn. J. Appl. Phy. 2017, 56, 04CE13.
Non-patent document 5: Yamaoka, H.; Yamashita, T.; Harada, A.; Sakaguchi, A.; Kinoshita, K.; Kishida, S.; Hayase, S.; Nokami, T.; Itoh, T. Chem. Lett. 2017, 46, 1832-1835.

### SUMMARY OF THE INVENTION

### Problem to be Solved by the Invention

While obtaining a stable and high-performance CB-RAM element was made possible to an acceptable degree as described previously, a further improvement in the CB-RAM element is called for to further control the characteristic of the CB-RAM element to a desired characteristic.

Therefore, the present disclosure is to solve such problems in a CB-RAM device or switching device and to provide a core technology to realize a high-performance CB-RAM device or switching device. In other words, the present disclosure is to achieve a further improvement in a CB-RAM device or switching device, and an applied device or appliance thereof.

### Means to Solve the Problem

A conductive bridge memory device being one embodiment of the present disclosure comprises: a memory cell including a first metal layer; a second metal layer; a first insulator layer having a first surface facing the first metal layer and a second surface facing the second metal layer and being a surface opposite to the first surface, and having a through hole penetrating between the first surface and the second surface; and a liquid layer being formed of liquid containing a liquid electrolyte impregnated in the through hole.

A switching device being one embodiment of the present disclosure comprises: a switching element including a first metal layer; a second metal layer; a first insulator layer having a first surface facing the first metal layer and a second surface facing the second metal layer and being a surface opposite to the first surface, and having a through hole penetrating between the first surface and the second surface; and a liquid layer being formed of liquid containing a liquid electrolyte impregnated in the through hole, wherein the switching device performs an electrical switching operation by electrical resistance between the first metal layer and the second metal layer changing to either a high resistance or a low resistance due to a change in voltage applied between the first metal layer and the second metal layer.

A manufacturing method of a conductive bridge memory device being one embodiment of the present disclosure includes: forming, on a surface of a first metal layer, a first insulator layer having a first surface being in contact with the surface and a second surface being a surface opposite to the first surface; forming a through hole penetrating between the first surface and the second surface by finely processing the first insulator layer; providing a liquid layer being in contact with the first metal layer by impregnating, in the through hole, liquid containing a liquid electrolyte; and forming, on the second surface side of the first insulator layer, a second metal layer being in contact with the liquid layer.

Moreover, a manufacturing method of a conductive bridge memory device being one embodiment of the present disclosure includes: forming a first insulator layer having a first surface, and a second surface being a surface opposite to the first surface; forming a through hole penetrating between the first surface and the second surface by finely processing the first insulator layer; embedding a first metal layer in a part in the through hole; providing a liquid layer being in contact with the first metal layer by impregnating, in the through hole in which the first metal layer is embedded, liquid containing a liquid electrolyte; and forming, on the second surface side of the first insulator layer, a second metal layer being in contact with the liquid layer.

Furthermore, a manufacturing method of a conductive bridge memory device being one embodiment of the present disclosure includes: forming, on a surface of a first metal layer, a first insulator layer having a first surface being in contact with the surface and a second surface being a surface opposite to the first surface; forming a second metal layer on a part of the second surface of the first metal layer: forming a through hole penetrating between the first surface and the second surface, a part of which through hole is covered by the second metal layer, by finely processing the first insulator layer; providing the first metal layer, and a liquid layer being in contact with the first metal layer, by impregnating, in the through hole, liquid containing a liquid electrolyte; and forming, on the second surface side of the first insulator layer, a second insulator layer so as to cover the second metal layer, and the liquid layer being exposed.

### Effects of the Invention

Embodiments of the present disclosure make it possible, or, in other words, the present disclosure makes it possible to achieve a further improvement in a CB-RAM device or switching device, and an applied device or appliance thereof.

### BRIEF DESCRIPTION OF THE DRAWINGS

FIG. 1A is a schematic cross-sectional view showing the structure of a Cu/HfO₂/Pt CB-RAM element.

FIG. 1B is a view explaining the principles of a switching process.

FIG. 2 is a schematic cross-sectional view showing a CB-RAM element included in a CB-RAM device according to a first aspect of a first embodiment of the present disclosure.

FIG. 3A is a schematic cross-sectional view showing the CB-RAM element included in the CB-RAM device according to a first variation of the first aspect of the first embodiment of the present disclosure.

FIG. 3B is a schematic cross-sectional view showing the CB-RAM element included in the CB-RAM device according to a second variation of the first aspect of the first embodiment of the present disclosure.

FIG. 3C is a schematic cross-sectional view showing the CB-RAM element included in the CB-RAM device according to a third variation of the first aspect of the first embodiment of the present disclosure.

FIG. 4 is a schematic cross-sectional view showing the CB-RAM element included in the CB-RAM device according to a second aspect of the first embodiment of the present disclosure.

FIG. 5 is a schematic cross-sectional view showing the CB-RAM element included in the CB-RAM device according to a third aspect of the first embodiment of the present disclosure.

FIG. 6 is a schematic cross-sectional view showing the CB-RAM element included in the CB-RAM device according to a fourth aspect of the first embodiment of the present disclosure.

FIG. 7 is a schematic cross-sectional view showing one example of the CB-RAM device according to the first embodiment of the present disclosure.

FIG. 8 is circuit diagram showing an exemplary configuration of the CB-RAM device according to the first embodiment of the present disclosure.

FIG. 9 is a graph, shown in the Weibull distribution, of the direct current measurement results of a set voltage (Vₛₑₜ) and a reset voltage (Vᵣₑₛₑₜ) in the CB-RAM element of the present disclosure.

FIG. 10 is a graph, shown in the Weibull distribution, of the measurement results of a resistance in a high resistance state (R_{HRS}) and a resistance in a low resistance state (R_{LRS}) in the CB-RAM element of the present disclosure.

FIG. 11 is a graph showing the measurement results of the resistance in the high resistance state (R_{HRS}) and the resistance in the low resistance state (R_{LRS}) by repeating of SET/RESET in the CB-RAM element of the present disclosure.

FIG. 12A is a graph showing the pulse measurement results of the set voltage (Vₛₑₜ) in the CB-RAM element of the present disclosure.

FIG. 12B is a graph showing the pulse measurement results of the reset voltage (Vᵣₑₛₑₜ) in the CB-RAM element of the present disclosure.

FIG. 13A is a schematic cross-sectional view showing a manufacturing process of the CB-RAM device of the first embodiment of the present disclosure.

FIG. 13B is a schematic cross-sectional view showing the manufacturing process of the CB-RAM device of the first embodiment of the present disclosure.

FIG. 14A is a schematic cross-sectional view showing a manufacturing process of the CB-RAM element according to a first aspect, which CB-RAM element is included in the CD-RAM device of the first embodiment of the present disclosure.

FIG. 14B is a schematic cross-sectional view showing the manufacturing process of the CB-RAM element according to the first aspect, which CB-RAM element is included in the CD-RAM device of the first embodiment of the present disclosure.

FIG. 14C is a schematic cross-sectional view showing the manufacturing process of the CB-RAM element according to the first aspect, which CB-RAM element is included in the CD-RAM device of the first embodiment of the present disclosure.

FIG. 14D is a schematic cross-sectional view showing the manufacturing process of the CB-RAM element according to the first aspect, which CB-RAM element is included in the CD-RAM device of the first embodiment of the present disclosure.

FIG. 15A is a schematic cross-sectional view showing a manufacturing process of the CB-RAM element according to a second aspect, which CB-RAM element is included in the CD-RAM device of the first embodiment of the present disclosure.

FIG. 15B is a schematic cross-sectional view showing the manufacturing process of the CB-RAM element according to the second aspect, which CB-RAM element is included in the CD-RAM device of the first embodiment of the present disclosure.

FIG. 15C is a schematic cross-sectional view showing the manufacturing process of the CB-RAM element according to the second aspect, which CB-RAM element is included in the CD-RAM device of the first embodiment of the present disclosure.

FIG. 16A is a schematic cross-sectional view showing a manufacturing process of the CB-RAM element according to a third aspect, which CB-RAM element is included in the CD-RAM device of the first embodiment of the present disclosure.

FIG. 16B is a schematic cross-sectional view showing the manufacturing process of the CB-RAM element according to the third aspect, which CB-RAM element is included in the CD-RAM device of the first embodiment of the present disclosure.

FIG. 16C is a schematic cross-sectional view showing the manufacturing process of the CB-RAM element according to the third aspect, which CB-RAM element is included in the CD-RAM device of the first embodiment of the present disclosure.

FIG. 16D is a schematic cross-sectional view showing the manufacturing process of the CB-RAM element according to the third aspect, which CB-RAM element is included in the CD-RAM device of the first embodiment of the present disclosure.

FIG. 17A is a schematic cross-sectional view showing a manufacturing process of the CB-RAM element according to a fourth aspect, which CB-RAM element is included in the CD-RAM device of the first embodiment of the present disclosure.

FIG. 17B is a schematic cross-sectional view showing the manufacturing process of the CB-RAM element according to the fourth aspect, which CB-RAM element is included in the CD-RAM device of the first embodiment of the present disclosure,

FIG. 17C is a schematic cross-sectional view showing the manufacturing process of the CB-RAM element according to the fourth aspect, which CB-RAM element is included in the CD-RAM device of the first embodiment of the present disclosure.

FIG. 17D is a schematic cross-sectional view showing the manufacturing process of the CB-RAM element according to the fourth aspect, which CB-RAM element is included in the CD-RAM device of the first embodiment of the present disclosure.

FIG. 17E is a schematic cross-sectional view showing the manufacturing process of the CB-RAM element according to the fourth aspect, which CB-RAM element is included in the CD-RAM device of the first embodiment of the present disclosure.

FIG. 18 is a graph showing the measurement results of the resistance maintaining characteristic in the GB-RAM element according to the first embodiment of the present disclosure.

FIG. 19 is an optical microscope image showing the Cu pattern before and after dropping [Bmim][TFSA] in which Cu(II)(TFSA)₂ is dissolved in a 0.4 mol/L concentration.

FIG. 20 is an optical microscope image showing the Cu pattern before and after dropping [Bmim][TFSA] in which Ag(I)(TFSA) is dissolved in a 0.4 mol/L concentration.

FIG. 21 is a graph showing the measurement results of a resistance change operation in the CB-RAM element according to the first embodiment of the present disclosure.

FIG. 22 is a graph, shown in the Weibull distribution, of the direct current measurement results of the set voltage (Vₛₑₜ) and the reset voltage (Vᵣₑₛₑₜ) in the CB-RAM element according to the first embodiment of the present disclosure.

FIG. 23 is a graph, shown in the Weibull distribution, of the measurement results of the resistance in the high resistance state (R_{HRS}) and the resistance in the low resistance state (R_{LRS}) in the CB-RAM element according to the first embodiment of the present disclosure.

FIG. 24 is a schematic view showing one example of a manufacturing method of a liquid electrolyte according to a fourth embodiment of the present disclosure.

### EMBODIMENT FOR CARRYING OUT THE INVENTION

Below, a number of embodiments related to a further improvement of a CB-RAM device or switching device and an applied device or appliance thereof, or elemental techniques contributing to the further improvement of the CB-RAM device will be described. In the present specification, “a CB-RAM (conductive bridge memory) element” refers to an element that can reversibly change, by control of a voltage applied between one pair of electrodes (specifically, a first metal layer and a second metal layer), the resistance value between the one pair of electrodes by forming a conductive path between the one pair of electrodes or causing the conductive path formed between the one pair of electrodes to disappear. Moreover, in the present specification, “a CB-RAM (conductive bridge memory) device” refers to the device overall, which device comprises the CB-RAM element to utilize a reversible resistance change. Furthermore, in the present specification, “a memory cell” refers to a portion to be a unit to reversibly change the resistance in the CB-RAM device. Moreover, in the present specification, “a memory” is not limited to a memory in a narrow sense, to which memory information is written as a resistance value and from which memory information reflected in the resistance value is read, so it suffices that information be reflected as the resistance value.

### First Embodiment

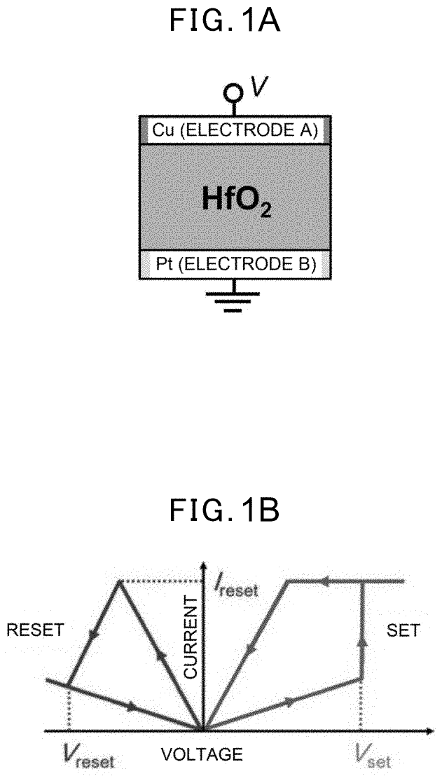

With advancement in the semiconductor manufacturing process, a CB-RAM element is believed to be further miniaturized in the future, and, in conjunction therewith, a size of a porous body layer is also expected to decrease. The present inventors have found that, with the CB-RAM element having electrode A (Cu in FIG. 1A)/porous body (HfO₂ (hafnia) in FIG. 1A)/electrode B (Pt in FIG. 1A) structure, a decrease in the size of the porous body layer causes variations in the number of pores included in the porous body layer to be exhibited as variations in the operation characteristic including the operating voltage or switching endurance of the CB-RAM element, such as V_{form}, Vₛₑₜ, and Vᵣₑₛₑₜ. The above-mentioned variations are believed to be caused by the position, size, shape and density of pores of a porous body constituting the porous body layer being introduced randomly when forming the porous body. However, controlling and introducing the pores in the porous body layer is difficult.

Then, according to the present embodiment, an element configuration is provided that gives guidelines to realize an optimal element structure to develop a high-performance CB-RAM device or switching device in which variations in an operation characteristic such as operating voltage or switching endurance are suppressed. In particular, the present embodiment provides design guidelines for the element structure of the high-performance CB-RAM device or switching device in which variations in the operation characteristic such as operating voltage or switching endurance are suppressed even when a further minituarization of the element is achieved.

[Structure of Memory Cell]

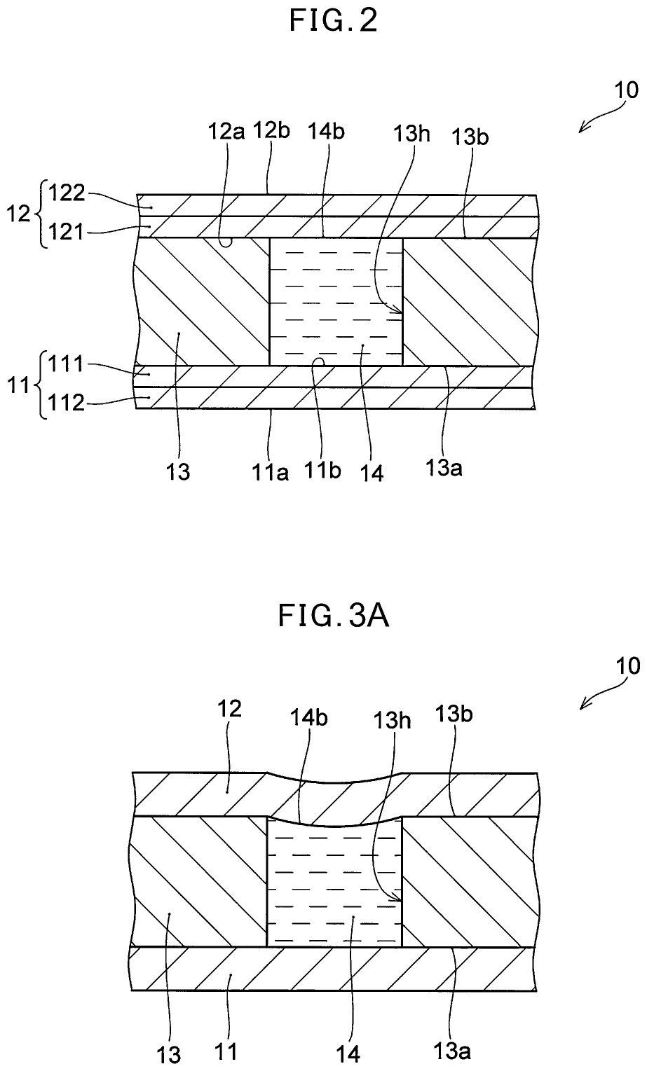

A conductive bridge memory (CB-RAM) device according to one embodiment of the present disclosure will be described with reference to FIG. 2. A CB-RAM element 10 included in the CB-RAM device according to the present embodiment, as shown with the structure of one example thereof in FIG. 2, comprises a first metal layer 11 (an electrode A); a second metal layer 12 (an electrode B); an insulator layer (a first insulator layer) 13 having a lower surface (a first surface) 13a facing the first metal layer 11 (the electrode A) and an upper surface (a second surface) 13b facing the second metal layer 12 (the electrode B) and being a surface opposite to the lower surface (the first surface) 13a, and having a through hole 13h penetrating between the lower surface (the first surface) 13a and the upper surface (second surface) 13b; and a liquid layer 14 being formed of liquid containing a liquid electrolyte impregnated in the through hole 13h. As described below, the CB-RAM element 10 constitutes a memory cell, along with a cell selection transistor, in the CB-RAM device. The memory cell constitutes the memory device along with a bit line and a word line to transmit a signal to write and/or read digital information. In the first metal layer 11, a surface facing the insulator layer (the first insulator layer) 13 is called an upper surface (a second surface) 11b and a surface opposite thereto is called a lower surface (a first surface) 11a, while, in the second metal layer 12, a surface facing the insulator layer (the first insulator layer) 13 is called a lower surface (a first surface) 12a and a surface opposite thereto is called an upper surface (a second surface) 12b.

Here, as shown in FIG. 2, for example, through holes mean pores penetrating with substantially the same thickness between the first surface (the lower surface) 13a of the insulator layer (the first insulator layer) 13, which first surface (the lower surface) 13a faces the first metal layer 11, and the second surface (the upper surface) 13b thereof, which second surface (the upper surface) 13b faces the second metal layer 12. Being substantially the same means having a tapered shape. so that sizes of holes can be different between the first surface and the second surface, and they can be formed using various etching and laser processing processes, for example.

As described previously, the present inventors have miniaturized the CB-RAM element and have made intensive studies in quest for performance improvement thereof. As a result, the present inventors have found that the first metal layer 11 and the second metal layer 12 could be connected reliably by the liquid layer 14 even with a thin through hole by forming the through hole 13h rather than using a porous body for the insulator layer (the first insulator layer). As a result, the reliability of connection between the first metal layer 11 and the second metal layer 12 could be improved and also a further minituarization could be achieved. Therefore, the present embodiment is characterized in having the through hole 13h in the insulator layer (the first insulator layer) 13, which through hole 13h penetrates between the lower surface 13a and the upper surface 13b.

The through hole 13h can have, as the planar view shape (the shape as viewed from a direction being perpendicular to the upper surface 13b of the insulator layer (the first insulator layer) 13), a shape including a circle, a polygon such as a quadrilateral, or a slit shape, or in short, being closed with a straight line, a curve, or both thereof, a circle included in which shape can be drawn. Here, in the present specification, a size of the through hole 13h is to refer to the diameter of a circle having the greatest size, which circle included in a shape of the through hole 13h can be drawn. As one example, the size of the through hole 13h is, for example, greater than or equal to 5 nm and less than or equal to 1000 nm.

While the number of through holes 13h formed is preferably one being the minimum number for each one memory cell (for each one CB-RAM element 10) from a point of view of miniaturizing the CB-RAM element 10 and thus the CB-RAM device, up to approximately five thereof can also be provided.

The above-mentioned through hole 13h can penetrate between the lower surface 13a and the upper surface 13b, can be formed in a tapered shape, and, moreover, can have a constricted portion or a bulging portion in the middle thereof. The above-mentioned through hole 13h can be formed by etching such as dry etching or wet etching, or laser processing, for example. Therefore, the position, size, shape, and density of the through hole 13h can be set desirably by the above-mentioned fine processing, allowing variations in the operation characteristic of the CB-RAM device 1 to be suppressed.

The insulator layer (the first insulator layer) 13 is suitably composed of an oxide or nitride containing one type of a metal element, such as SiO₂ (silicon oxide), SiN (silicon nitride), Al₂O₃ (aluminum oxide), AlN (aluminum nitride), HfO₂ (hafnium oxide), TiO₂ (titanium oxide), or Ta₂O₅ (tantalum oxide), an oxide containing a metal element in a plurality, such as Si—Al—O (aluminum silicate), or an oxynitride such as Si—O—N(nitridosilicate). The insulator layer (the first insulator layer) 13 is suitably composed of an insulator into which pores are difficult to be introduced or not introduced, such as an amorphous body. In this way, only the through hole 13h is generally provided in the insulator layer 13, so that variations in the operation characteristic of the CB-RAM device 1 are further suppressed.

The first metal layer 11 and the second metal layer 12 are suitably composed of metals, which are different from each other in electrochemical activity, and function as one pair of electrode layers (the electrode A and the electrode B) to deliver and receive the charges with the liquid layer 14. For example, a metal having low electrochemical activity, or in other words, a metal being electrochemically stable is used for the first metal layer 11, for example. In that case, a metal for the first metal layer 11 can include a metal such as Pt, Au, Ir, Ru, Rh, or W, or an alloy of these metals, for example, and the layer thickness of the first metal layer 11 is 20 nm, for example. Moreover, a metal being electrochemically active and easily ionized is used for the second metal layer 12. In that case, a metal for the second metal layer 12 can include a metal such as Cu, Ag, Ti, Zn, or V, or an alloy of these metals, for example, and the layer thickness of the second metal layer 12 is 50 nm, for example. However, a metal being electrochemically active and easily ionized can be used as a metal for the first metal layer 11, and an electrochemically stable metal can be used as a metal for the second metal layer 12. The metal for the second metal layer 12 (which metal includes a metal formed of a single element and an alloy formed of a plurality of elements) can differ in ionization tendency from the metal for the first metal layer 11 (which metal includes a metal formed of a single element and an alloy formed of a plurality of elements). Metals “whose ionization tendencies differ” being referred to here refer to metals of the first metal layer 11 and the second metal layer 12 of a portion being in contact with the liquid layer 14 and are independent of whether the entirety of the first metal layer 11 and the second metal layer 12 is composed of these metals. Moreover, the first metal layer 11 or the second metal layer 12 can be formed of a plurality of layers. For example, in a case that a metal easily oxidized, such as the above-mentioned Cu, is used as a metal for the first metal layer 11 or the second metal layer 12, in the first metal layer 11 or the second metal layer 12, a layer being in contact with the liquid layer 14 can be, as an electrode layer (see a first layer 111 of the first metal layer 11 or a first layer 121 of the second metal layer 12 shown in FIG. 2), composed of the metal easily oxidized, and a layer being provided opposite to the liquid layer 14 with respect to the electrode layer (the first layer) 111, 121 can be, as a different layer (see a second layer 112 of the first metal layer 11 or a second layer 122 of the second metal layer 12 shown in FIG. 2), composed of a metal being different from the metal easily oxidized. In other words, the second layer 112 of the first metal layer 11 or the second layer 122 of the second metal layer 12 functions as a cap layer to prevent oxidation of the electrode layer 111, 121. For example, the cap layer (the second layer) 112, 122 contains at least one type of metal to be selected from a group consisting of Au, Ni, Ta, Nb, W, Pt, and Mo, and preferably contains Ta. The layer thickness of the cap layer 112, 122 is 30 nm, for example. While the cap layer 112, 122 can be provided opposite to the liquid layer 14 with a different layer being interposed with respect to the electrode layer 111, 121, it is preferably formed to be in contact with the electrode layer 111, 121 to increase the effect of preventing oxidation of the electrode layer 111, 121. Moreover, in a case that an easily corroding metal such as the above-mentioned Cu is used as a metal for the first metal layer 11 or the second metal layer 12, for example, in the first metal layer 11 or the second metal layer 12, the first layer 111, 121 as an electrode layer can be composed of the easily corroding metal and the second layer 112, 122 as a different metal layer can be composed of a metal being difficult to corrode. In other words, in this case, the second layer 112, 122 functions as a corrosion preventing layer to prevent corrosion of the electrode layer. As a metal for the corrosion preventing layer, a metal such as Ta can be exemplified. The layer thickness of the corrosion preventing layer is 1 to 10 nm, for example, and various characteristics (for example, a resistance retaining characteristic) of the CB-RAM element can be controlled by the layer thickness of the corrosion preventing layer. Moreover, a different layer can be provided between the electrode layer and the cap layer or opposite to the electrode layer with respect to the cap layer, which different layer includes a barrier layer to prevent diffusion of a metal constituting the electrode layer 111, 121. For example, the barrier layer contains at least one type of metal to be selected from a group consisting of W, Ta, Ti, TiN, TiC, TaN, TaC, and W₂N. The layer thickness of the barrier layer is 25 nm, for example. The barrier layer is introduced, for example, in a case that the metal constituting the electrode layer 111, 121 and the metal constituting the cap layer 112, 122 easily diffuse with each other. Specifically, a case can be exemplified in which the electrode layer 111, 121 is composed of Cu or Ni and the cap layer 112, 122 is composed of Au.

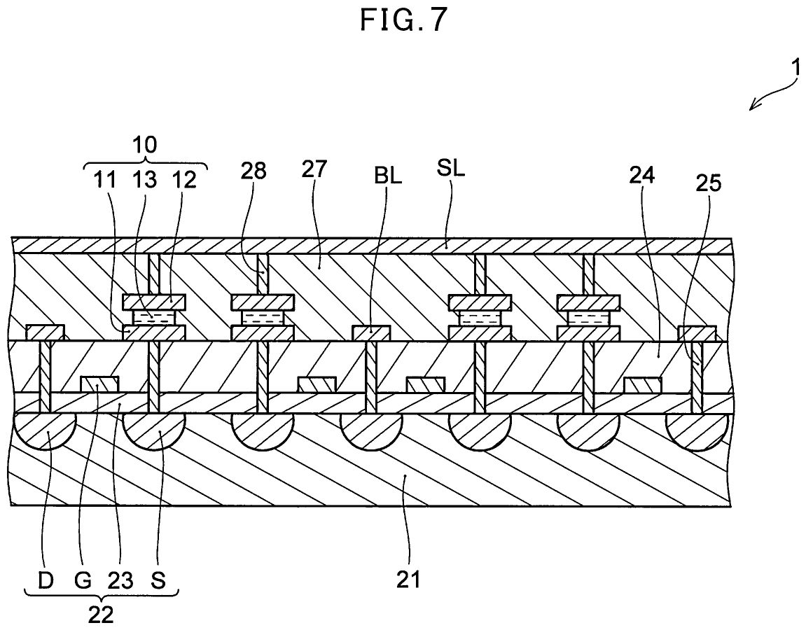

For example, in a case that Pt is selected as the first metal layer 11 or the second metal layer 12 and SiO₂ is selected as the insulator layer (the first insulator layer) 13, the adhesion is not sufficiently obtained between the insulator layer (the first insulator layer) 13 and the first metal layer 11 or the second metal layer 12. Therefore, an adhesion layer can be interposed between the first metal layer 11 and the insulator layer (the first insulator layer) 13 and/or between the second metal layer 12 and the insulator layer (the first insulator layer) 13, which adhesion layer is composed of a metal whose adhesion with respect to the insulator layer (the first insulator layer) 13 is superior to that of the first metal layer 11. Metals for the adhesion layer can include Ta, Ti, and Cr. The layer thickness of the adhesion layer is 1 nm, for example. Moreover, in a case that the lower surface 11a of the first metal layer 11 is provided so as to be in contact with an insulator layer (not shown in FIG. 2) such as an interlayer insulating film 24 (see FIG. 7) described below, an adhesion layer being similar to what is described above can be interposed between the first metal layer 11 and the above-mentioned insulator layer. Furthermore, in a case that the upper surface 12b of the second metal layer 12 is provided so as to be in contact with an insulator layer (not shown in FIG. 2) such as an interlayer insulating film 27 (see FIG. 7) described below, an adhesion layer being similar to what is described above can be interposed between the second metal layer 12 and the insulator layer.

The liquid layer 14 is composed of a liquid electrolyte. Here, in the present specification, “the liquid electrolyte” refers to a liquid in which ions can move in response to a voltage applied between the first metal layer 11 and the second metal layer 12. While the liquid electrolyte is suitably an ionic liquid, it is not limited thereto as long as it is a liquid that can move ions. Here, in the present specification, “the ionic liquid” is a concept including not only the ionic liquid itself, but also a solvated ionic liquid and a mixed ionic liquid in which is mixed a plurality of ionic liquids and/or the solvated ionic liquid. Moreover, “solvation” refers to a state in which molecules of a solvent surround molecules or ions of a solute in a solution to create a group of molecules. Furthermore, “the solvated ionic liquid” means an ionic liquid having such solvation. The mixed ionic liquid is advantageous in that, for example, the viscosity thereof can be adjusted by mixing a solvated ionic liquid, and an ionic liquid having a viscosity (viscosity coefficient) being smaller than that of the above-mentioned solvated ionic liquid.

While the above-described ionic liquid itself can include 1-Butyl-3-methylimidazolium ([Bmim])·bis (trifluoromethyl)sulfonylamide ([TFSA]), it is not limited thereto. Moreover, while a mixed ionic liquid in which are mixed a plurality of ionic liquids can include 1-Butyl-3-methylimidazolium bis (trifluoromethyl)sulfonylamide ([Bmim] [TFSA]), it is not limited thereto.

“TFSA” is also abbreviated as [Tf₂N] and also often denoted, in reagent catalogs and documents, as “bis(trifluoromethylsulfonyl)imide” ([TFSI]). However, “imide” is specified in the IUPAC method as “an amido compound which connected with two carbonyl groups”, so that [Tf₂N] being named as “bis(trifluoromethylsulfonyl)amide” is correct when naming it in accordance with the IUPAC method. The “(trifluoromethylsulfonyl)imide” can be said to be a name according to the IUPAC method. In the specification, we will use [TFSA] in accordance with the IUPAC method.

At least one type of solvent to be selected from a group consisting of, for example,

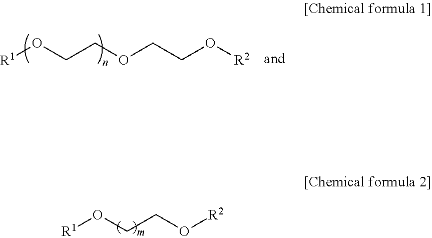

can be used as a solvent of the above-described solvated ionic liquid, but the solvent is not limited thereto
(where n is the number of ethyleneoxy groups being 1 or 2; m is the number of methylene groups, which is an integer being any one of 1 to 3: each of R¹, R² can be the same or different; R¹ denotes an alkyl group whose number of carbons is between 1 and 6, an alkenyl group whose number of carbons is between 2 and 6, an alkylnyl group whose number of carbons is between 2 and 6, a trimethysilyl group, a triethysilyl group, or a t-butyldimethylsilyl group; R² denotes an alkyl group whose number of carbons is between 1 and 16, an alkenyl group whose number of carbons is between 2 and 6, an alkylnyl group whose number of carbons is between 2 and 6, a trimethysilyl group, a triethysilyl group, or a t-butyldimethylsilyl group; and the alkyl group can contain therein an ether functional group, a thioether functional group).

While a metal ion being a solute constituting the solvated ionic liquid is desirably a copper ion that can be a filament component, it is not limited to a filament-constituting component metal (a metal material of the first metal layer 11). For example, a metal ion such as precious ion species including a silver (Ag) ion, a gold (Au) ion, a palladium (Pd) ion, a rhodium (Rh) ion, a ruthenium (Ru) ion, a platinum (Pt) ion, a metal ion such as cobalt (Co) and nickel (Ni), and a lanthanoid metal ion such as Europium (Eu) can be utilized. Moreover, a plurality of these metal ions can be mixed. In other words, even in a case that copper is used as a material for the first metal layer 11 and a filament is formed of copper, the above-mentioned various metal ions can be used as a solute of the solvated ionic liquid, or a copper ion and these metal ions can be mixed. The proportion of the metal ion of the solvated ionic liquid with respect to the overall metal constituting the filament is very small.

While a counter anion constituting the solvated ionic liquid is desirably bis(trifluoromethylsulfonyl)amide (N(SO₂CF₃)₂⁻:TFSA), bis(fluorosulfonyl)amide (N(SO₂F)₂⁻:FSA), it suffices to be an anion species to be liquid in a case that it is solvated, and the other ones can include AlCl₄⁻, BF₄⁻, PF₆⁻, SbF₆⁻, MeSO₃⁻, CF₃SO₃⁻, NO₃⁻, CF₃COO⁻, RCOO⁻, RSO₄⁻, RCH(NH₂)COO⁻, SO₄²⁻, CIO₄⁻, (HF)_{2.3}F⁻ (Here, R denotes H, an alkyl group, an alkyloxy group), but they are not limited thereto.

Moreover, as the above-described ionic liquid having the small viscosity coefficient, at least one type to be selected from a group consisting of, for example,

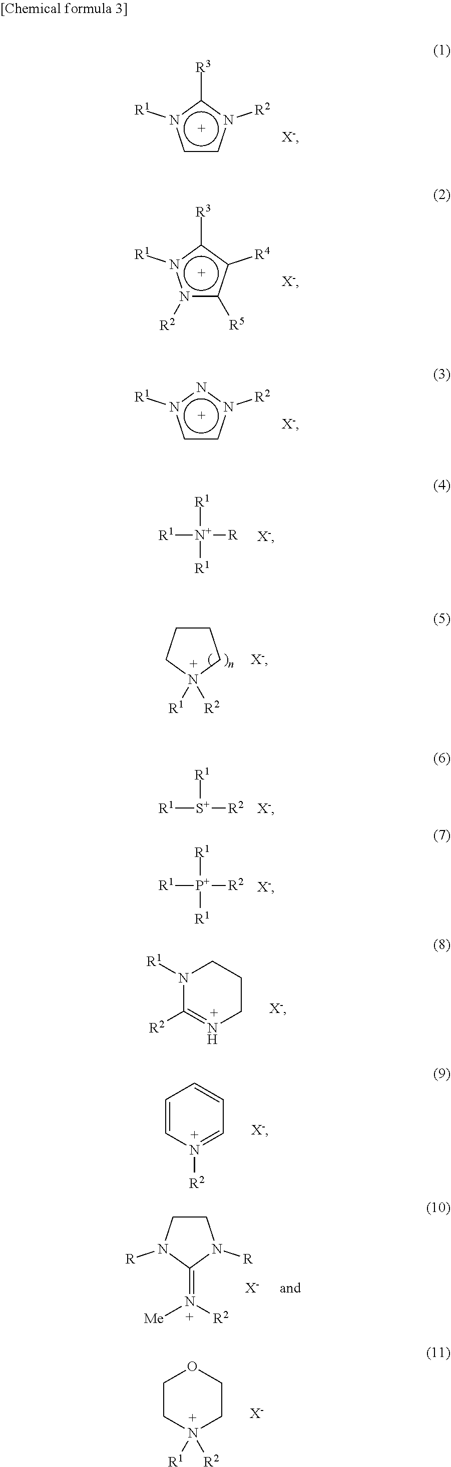

can be used,
(where R¹ can be the same or different in the above-mentioned respective chemical formulas, and denotes an alkyl group whose number of carbons is between 1 and 6, or an alkenyl group whose number of carbons is between 2 and 6; R² can be the same or different in the above-mentioned respective chemical formulas, and denotes a hydrogen atom, an alkyl group whose number of carbons is between 1 and 16, an alkenyl group whose number of carbons is between 2 and 6, or an alkoxy group. The alkyl group can contain therein an ether functional group, a thioether functional group. R³ can be the same or different in the above-mentioned respective chemical formulas, and denotes a hydrogen atom, a phenyl group, a methyl group, or an isopropyl group. n in chemical formula (5) denotes the number of methylene units, where n=1 or 2. In chemical formula (8), R¹ and R² can have carbon chains connected mutually, in which case they denote a trimethylene group, a tetramethylene group, a pentamethylene group, a hexamethylene group, or a heptamethylene group. Anion (X) in the ionic liquid can be the same or different in the above-mentioned respective chemical formulas, and is AlCl₄⁻, BF₄⁻, PF₆⁻, SbF₆⁻, N(SO₂CF₃)₂⁻, N(SO₂F)₂⁻, N(CN)2⁻, MeSO₃⁻, MeSO₄⁻, CF₃SO₃⁻, NO₃⁻, CF₃COO⁻, RCOO⁻, RSO₄⁻, RCH(NH₂)COO⁻, SO₄²⁻, CIO₄⁻, Me₂PO₄⁻, (HF)_{2.3}F⁻ (Here, R denotes H, an alkyl group, an alkyloxy group), but they are not limited thereto.

A further specific example of a cation and an anion constituting the ionic liquid having the small viscosity coefficient can include:

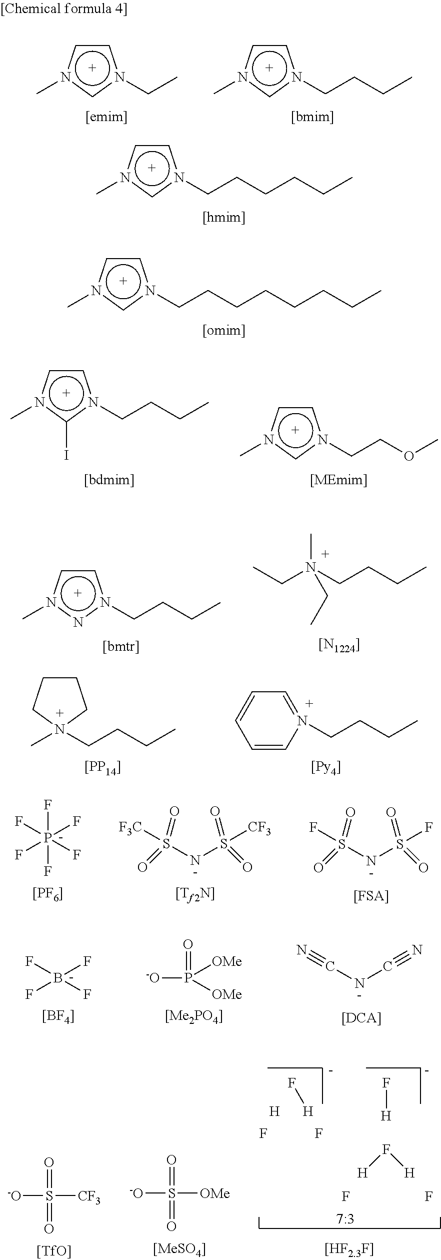

but it is not limited thereto.

The above-mentioned solvated ionic liquid or ionic liquid having the small viscosity coefficient is not limited to the one type in the above-mentioned example, and can be a mixture of a plurality of types. Moreover, the mixture ratio (the mole ratio) of the solvated ionic liquid and the ionic liquid having the low viscosity is adjusted as needed in accordance with the shape, size, or density of the through hole 13h of the insulator layer (first insulator layer) 3 used.

Moreover, incorporating, in the solvated ionic liquid or ionic liquid having the low viscosity, or a mixed ionic liquid in which these are mixed, a metal salt to be dissolved therein further improves the operation characteristic of the CB-RAM function.

A cation of a metal salt to be dissolved in the mixed ionic liquid is not limited to a filament-constituting metal, or, in other words, a metal of the first metal layer 11, so that it can be a metal salt capable of being dissolved in the ionic liquid having the small viscosity coefficient, or the solvated ionic liquid. In this case, a metal having a smaller ionization tendency than that of the metal of the first metal layer 11 is desirable. In other words, in a case that copper is used as the first metal layer 11, a silver salt, a gold salt, a palladium salt, a rhodium salt, a ruthenium salt, a platinum salt, and the like are possible, for example. In particular, adding the silver salt could substantially improve the CB-RAM function. Moreover, this metal salt can be not only a monosalt, but also a double salt.

While, as an anion of a metal salt to be dissolved in the mixed ionic liquid, bis(trifluoromethylsulfonyl)amide (N(SO₂CF₃)₂⁻:TFSA), bis(fluorosulfonyl)amide (N(SO₂F)₂⁻:FSA) are desirable, it suffices to be an anion species to be liquid in a case of solvating with a metal ion, and the other ones can include AlCl₄⁻, BF₄⁻, PF₆⁻, SbF₆⁻, MeSO₃⁻, CF₃SO₃⁻, NO₃⁻, CF₃COO⁻, RCOO⁻, RSO₄⁻, RCH(NH₂)COO⁻, SO₄²⁻, CIO₄⁻, (HF)_{2.3}F⁻ (Here, R denotes H, an alkyl group, an alkyloxy group), but they are not limited thereto. Moreover, a plurality of these anions can be mixed.

The ionic liquid having the low viscosity or the solvated ionic liquid containing a metal salt or a metal ion can be a single mixed ionic liquid or a plurality of mixed ionic liquids, or a solvated ionic liquid composed of different types of metal ions.

A number of aspects of the CB-RAM element 10 to be applied to the CB-RAM device 1 of the present embodiment will be described below. In the attached drawings, the same letters are affixed to parts having the same functions.

[First Aspect of CB-RAM Element]

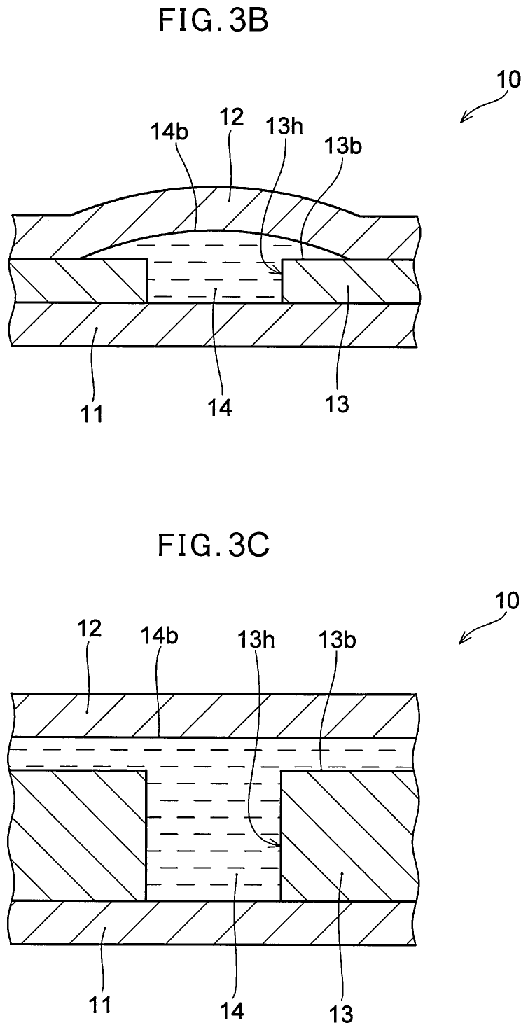

As shown in FIG. 2, in the CB-RAM element 10 according to a first aspect, an upper surface 14b of the liquid layer 14 is suitably flush with the upper surface 13b of the insulator layer (the first insulator layer) 13. However, as in a first variation shown in FIG. 3A, the CB-RAM element 10 can be made to function even when the upper surface 14b of the liquid layer 14 is slightly recessed or slightly bulged with respect to the upper surface 13b of the insulator layer (the first insulator layer) 13.

Moreover, in a second variation shown in FIG. 3B, the liquid layer 14 reaches not only into the through hole 13, but also to the upper surface 13b of the insulator layer (the first insulator layer) 13 in the vicinity of an opening of the through hole 13h, and the upper surface 14b thereof protrudes from the upper surface 13b of the insulator layer (the first insulator layer) 13. In other words, in this CB-RAM element 10, liquid in an amount not lacking with respect to the volume of the through hole 13h is impregnated in the through hole 13h. Therefore, there is an advantage that no problem of a shortage of filling of a liquid electrolyte into the through hole 13h occurs.

Furthermore, in a third variation shown in FIG. 3C, the liquid layer 14 overflows to the upper surface 13b from the through hole 13h of the insulator layer (the first insulator layer) 13 and is interposed between the second metal layer 12 and the upper surface 13b of the insulator layer (the first insulator layer) 13. In other words, in this CB-RAM element 10, a liquid electrolyte in an amount being sufficiently large with respect to the volume of the through hole 13h is impregnated in the through hole 13h. In this way, the CB-RAM element can be made to function even when the liquid layer 14 is provided.

[Second Aspect of CB-RAM Element]

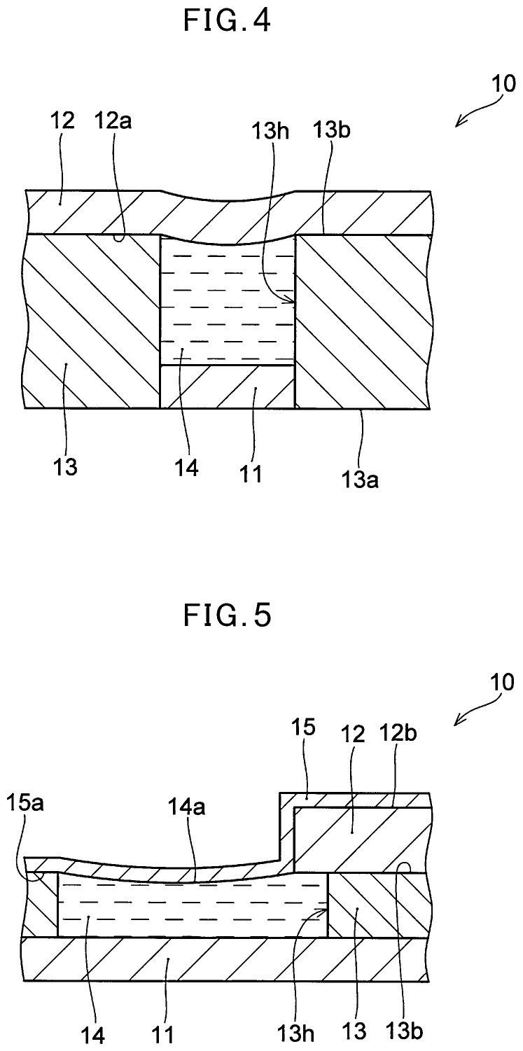

The CB-RAM element 10 according to a second aspect, as shown in FIG. 4, is different from that according to the first aspect in that the first metal layer 11 is embedded in a part of the through hole 13h of the insulator layer (the first insulator layer) 13. Then, the liquid layer 14 is provided in the through hole 13h between the first metal layer 11 being embedded therein and the second metal layer 12. Such a CB-RAM element 10 is advantageous in that a finer CB-RAM element and thus a finer CB-RAM device can be prepared since the CB-RAM element 10 is defined only by a forming area of the through hole 13h as the first metal layer 11 is embedded in the through hole 13h. While the entirety of the first metal layer 11 is embedded in the through hole 13h in FIG. 4, a part thereof can be embedded in the through hole 13h.

[Third Aspect of CB-RAM Element]

As shown in FIG. 5, the CB-RAM element 10 according to a third aspect is different from the above-described aspect in that the second metal layer 12 is formed so as to cover, not the entirety of an upper surface 14a of the liquid 14, but only a part thereof. In other words, the through hole 13h is formed also below the second metal layer 12, and the second metal layer 12 faces the first metal layer 11 across the liquid layer 14. Then, another insulator layer (a second insulator layer) 15 is formed so as to cover the second metal layer 12, and the liquid layer 14 not covered by the second metal layer 12. Such a CB-RAM element 10 is advantageous in that the second metal layer 12 protruding to the upper surface 14a of the liquid layer 14 causes an operating area of the CB-RAM element 10 to be defined by an area between the first metal layer 11 and the second metal layer 12. Moreover, the element structure is easy to minituarize from a viewpoint of the manufacturing process.

[Fourth Aspect of CB-RAM Element]

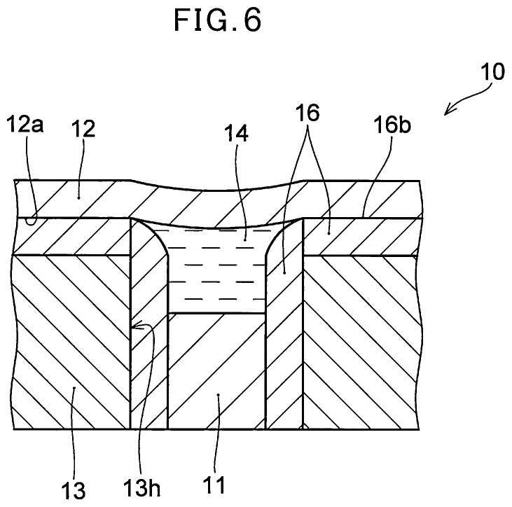

As shown in FIG. 6, the CB-RAM element 10 according to a fourth aspect is different from the above-described aspect in using an insulator layer (a third insulator layer) 16 composed of a different insulating material being better in the wettability with respect to a liquid electrolyte than the insulating material constituting the insulator layer (the first insulator layer) 13. The insulator layer (the third insulator layer) 16 is formed so as to cover the inner wall of the through hole 13h, and the liquid layer 14 is provided by the liquid electrolyte being filled into the through hole 13h surrounded by the insulator layer (the second insulator layer) 15.

The insulating material constituting the insulator layer in which the through hole is provided and the liquid electrolyte used are poorly compatible with each other, so that it can be difficult to impregnate the liquid electrolyte into the through hole. The present aspect is advantageous in that the liquid electrolyte can be easily impregnated in the through hole 13h by selecting a different insulating material having a good wettability with the liquid electrolyte used and separately providing the insulator layer (the third insulator layer) 16 composed of this insulating material.

[CB-Ram Device]

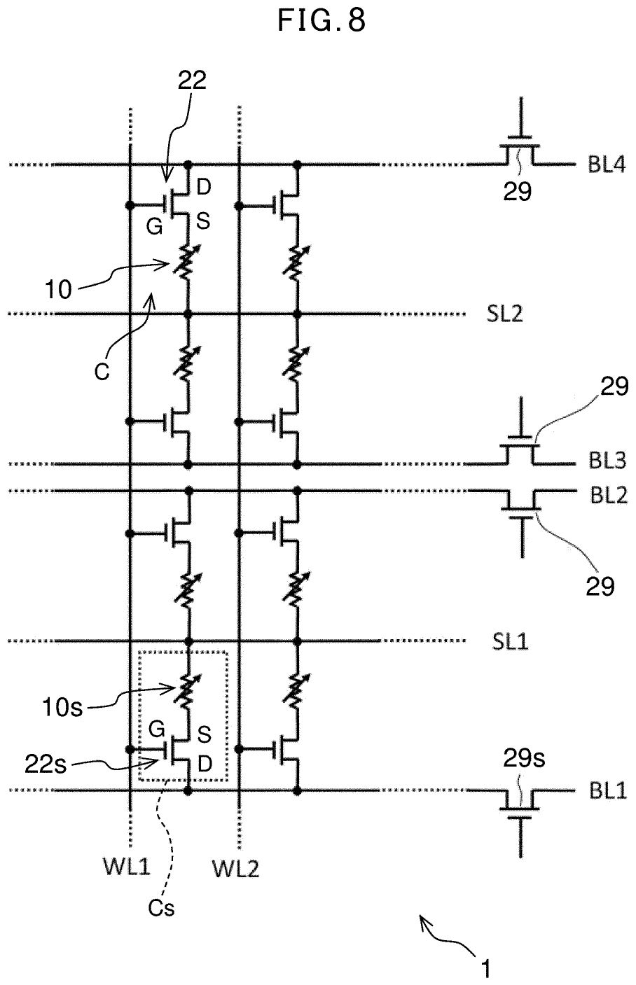

Next, one example of the CB-RAM device 1 including the above-described CB-RAM element 10 will be described below with reference to FIGS. 7 and 8. As shown in FIG. 7, the CB-RAM device 1 comprises a substrate 21: a cell selection transistor 22 formed in the substrate 21; the interlayer insulating film 24 formed so as to cover the cell selection transistor 22; a contact plug 25 being connected to the cell selection transistor 22 and penetrating the interlayer insulating film 24; a bit line BL being connected to the contact plug 25 and formed on a surface of the interlayer insulating film 24; the above-described CB-RAM element 10 being connected to the contact plug 25 and formed on the surface of the interlayer insulating film 24; the interlayer insulating film 27 formed so as to cover the bit line BL and the CB-RAM element 10; a contact plug 28 being connected to the CB-RAM element 10 and penetrating the interlayer insulating film 24; and a source line SL being connected to the contact plug 28 and formed on a surface of the interlayer insulating film 27.

The substrate 21 is a substrate to be a base for forming the cell selection transistor 22. While the substrate 21 is composed of a semiconductor material such as a single crystalline Si or single crystalline SiGe, for example, it is not limited thereto as long as the cell selection transistor 22 can be formed. For example, the substrate 21 can be composed of an insulator material such as glass.

The cell selection transistor 22 functions as a switch to control current flowing to the CB-RAM element 10 and comprises, for example, a source S and a drain D formed on a surface of the substrate 21; a gate insulating film 23 covering the substrate 21; and a gate G formed over the gate insulating film 23 above an area between the source S and the drain D. While the cell selection transistor 22 is composed of a MOS (Metal-oxide semiconductor) transistor, for example, it is not limited thereto. For example, the cell selection transistor 22 can be composed of a bipolar transistor. While not illustrated in FIG. 7, the gate G is connected to word lines (see WL1, WL2 in FIG. 8).

The interlayer insulating film 24 is a layer to electrically connect the cell selection transistor 22 to the bit line BL and the CB-RAM element 10 via the contact plug 25. The bit line BL is connected to the drain D of the cell selection transistor 22, and the first metal layer 11 of the CB-RAM element 10 is connected to the source S of the cell selection transistor 22.

The interlayer insulating film 27 is a layer to electrically connect the CB-RAM element 10 to the source line SL via the contact plug 28. The source line SL is connected to the second metal layer 12 of the CB-RAM element 10.

The bit line BL is a wiring to read information from the CB-RAM element 10 or write information to the CB-RAM element 10 and is connected to the drain D of the cell selection transistor 22. The source line SL is a wiring to provide a reference potential to the CB-RAM element 10 and is connected to the second metal layer 12 of the CB-RAM element 10. A word line (see WL1, WL2 in FIG. 8) is a wiring to send a control signal to control ON/OFF of the gate G of the cell selection transistor 22 to read information from the CB-RAM element 10 or write information to the CB-RAM element 10 and is connected to the gate G of the cell selection transistor 22. ON/OFF of the respective bit line BL is controlled by a bit line selection transistor (see 29 in FIG. 8).

When viewed from a direction being perpendicular to the surface of the substrate 21, a bit line BL extends in a row direction and is provided in a plurality so as to be arranged in parallel in a column direction (see BL1 to BL4 in FIG. 8) and a word line extends in a column direction and is provided in a plurality so as to be arranged in parallel in the row direction (see WL1, WL2 in FIG. 8). Moreover, a source line SL extends in the row direction between neighboring bit lines BL and is provided in a plurality so as to be arranged in parallel in the column direction (see SL1, SL2 in FIG. 8). Then, as shown in FIG. 8, a memory cell C including the CB-RAM element 10 and the cell selection transistor 22 is arranged in a matrix in the vicinity of each intersection of bit lines BL1 to BL4 and word lines WL1, WL2. The numbers of the bit lines BL1 to BL4, the word lines WL1, WL2, and source lines SL1, SL2 shown in FIG. 8 are set for convenience of explanations, so that, in practice, these numbers are set in accordance with the number of rows and the number of columns of the matrix being composed of a large number of memory cells SC.

[Operation of CB-RAM Device]

Next, with reference to FIG. 8, an operation at the time of set of the memory cell C (the CB-RAM device) in an array, according to the embodiment will be described. Here, a case in which a memory cell Cs shown in a portion surrounded by broken lines in FIG. 8 is selected will be described. As described previously, set is a process of rewriting from high resistance to low resistance. First, a cell selection transistor 22s being connected to the bit line BL1 connected to the memory cell Cs is turned on. Next (or simultaneously therewith), a voltage is applied to the word line WL1 being connected to the gate G of the cell selection transistor 22s connected to a CB-RAM element 10s, and the cell selection transistor 22s is turned on. A bias voltage to be applied to the bit line BL1 is set so as to take a positive value with respect to the source line SL1 (set so as to be negative in a case that the second metal layer 12 is composed of a metal being electrochemically stable), and the absolute value thereof is set to be approximately the same as or slightly greater than the absolute value of the voltage required for set.

The source line SL1 connected to the memory cell Cs being brought to be at a reference potential, for example, a ground potential 0V, allows a current path from the bias voltage of the bit line BL1 to the ground potential to be created, which current path goes through a bit line selection transistor 29s, the cell selection transistor 22s, and the CB-RAM element 10s, and the bias voltage is distributed, in accordance with the ratio of a resistance R in the high resistance state of the CB-RAM element 10s and a channel resistance r of the cell selection transistor 22s, a channel resistance of the bit line selection transistor 29s, to the CB-RAM element 10s and a channel resistance r′ of the bit line selection transistor 29s. The r and r′ are set such that the sum of r and r′ is less than R and greater than a resistance R′ in the low resistance state of the CB-RAM element 10s. In other words, they are set such that R′<r+r′<R is satisfied. The resistance of the CB-RAM element 10s decreases from R to R′ at the instance of set, so that current flowing through the CB-RAM element 10s immediately after set is controlled by r+r′. Thereafter, when the bias voltage is brought back to 0V, set is completed.

On the other hand, while reset being the switching process from low resistance to high resistance is also carried out with the same procedure as that for the above-described set process, the point to bear in mind is that the bias voltage (with respect to the source line BL1) to be applied to the selection bit line BL1 will have positive and negative reversed with respect to the case of set. In other words, in a case that the second electrode layer 12 is composed of a metal being easily ionized electrochemically, the bias voltage to be applied to the selection bit line BL1 is set to have a negative value with respect to the source line SL1. For example, the selection bit line BL1 is set to be at the ground potential 0V and the source line SL1 is set to have a positive value. Thereafter, once the bias voltage is brought back to 0V, reset is completed.

For reading, the gate voltage is adjusted such that both channel resistances of the cell selection transistor 22s and the bit line selection transistor 29s are brought to be sufficiently less than the value r of the low resistance of the CB-RAM device 10s, and detecting current flowing when a prespecified voltage is applied allows the resistance of the CB-RAM device 10s to be determined.

### EXAMPLES

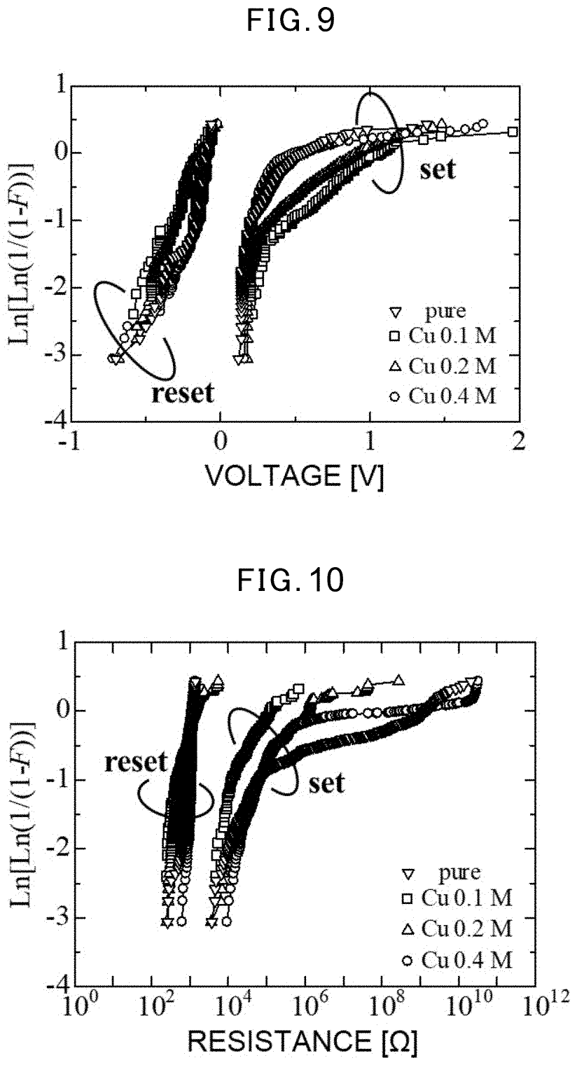

To confirm the effects of the above-described embodiments, the present inventors prepared a CB-RAM element according to the second variation in the first aspect described above and measured the set voltage (Vₛₑₜ) and the reset voltage (Vᵣₑₛₑₜ) by applying a direct current voltage to the CB-RAM element. The measurement results are shown in the Weibull distribution in FIG. 9. Five types of liquids below were used as the liquid electrolyte of the liquid layer:

Example 1: [Bmim][TFSA] (called “pure” in FIGS. 9 and 10)

Example 2: [Bmim][TFSA] of Example 1, in which Cu(II)(TFSA)₂ is dissolved in a 0.1 mol/L concentration (called “Cu 0.1 M” in FIGS. 9 and 10)

Example 3: [Bmim][TFSA] of Example 1, in which Cu(II)(TFSA)₂ is dissolved in a 0.2 mol/L concentration (called “Cu 0.2 M” in FIGS. 9 and 10)

Example 4: [Bmim][TFSA] of Example 1, in which Cu(II)(TFSA)₂ is dissolved in a 0.4 mol/L concentration (called “Cu 0.4 M” in FIGS. 9, 10, 12A, 12B, and 18)

Example 5: [Bmim][TFSA] of Example 1, in which Ag(I)(TFSA) is dissolved in a 0.4 mol/L concentration (called “Ag 0.4 M” in FIG. 18)

Example 4 was in a substantially saturated state.

As shown in FIG. 9, in Examples 1 to 4, variations in Vₛₑₜ and Vᵣₑₛₑₜ were, respectively, approximately 1.5V and 0.6V. On the contrary, in the CB-RAM element in which the liquid electrolyte was impregnated in the pores of the porous body layer, the variations in Vₛₑₜ and Vᵣₑₛₑₜ were, respectively, approximately 6V and 3V. Based on these results, the variations in Vₛₑₜ and Vᵣₑₛₑₜ of the CB-RAM element of Examples 1 to 4 were confirmed to be substantially reduced.

Moreover, in Examples 1 to 4, a resistance in a high resistance state R_{HRS} and a resistance in a low resistance state R_{LRS} were measured in Examples 1 to 4. The measurement results are shown in the Weibull distribution in FIG. 10. As shown in FIG. 10, the variations were confirmed to be small also in R_{HRS} and R_{LRS}.

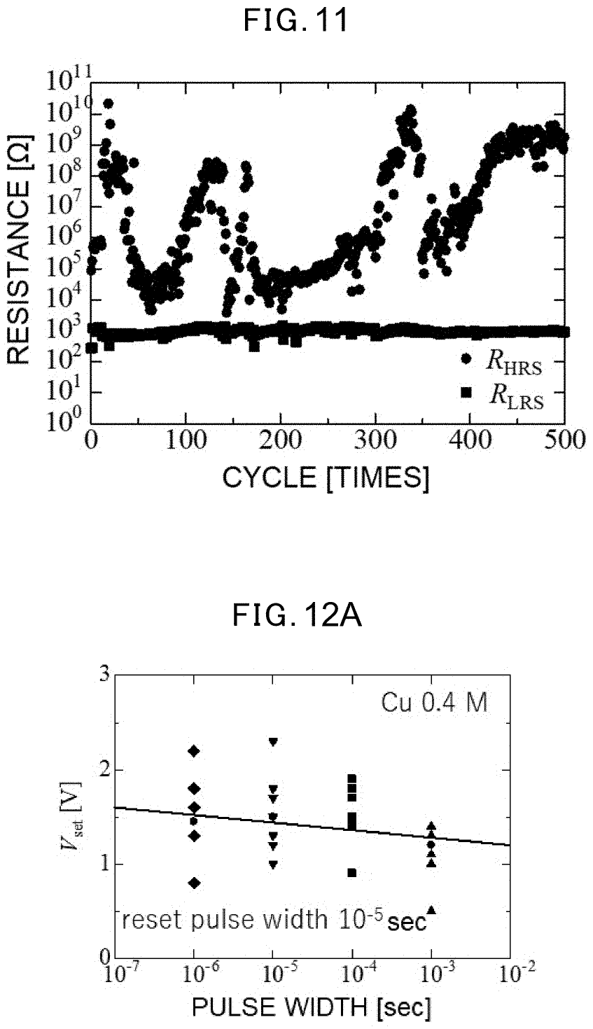

Moreover, changes in R_{HRS} and R_{LRS} by repeating of SET/RESET in Example 1 (“pure”) were measured. The measurement results are shown in in FIG. 11. While there were points of small and large variations aperiodically in R_{HRS}, no dependencies of R_{HRS} and R_{LRS} on the number of times were observed.

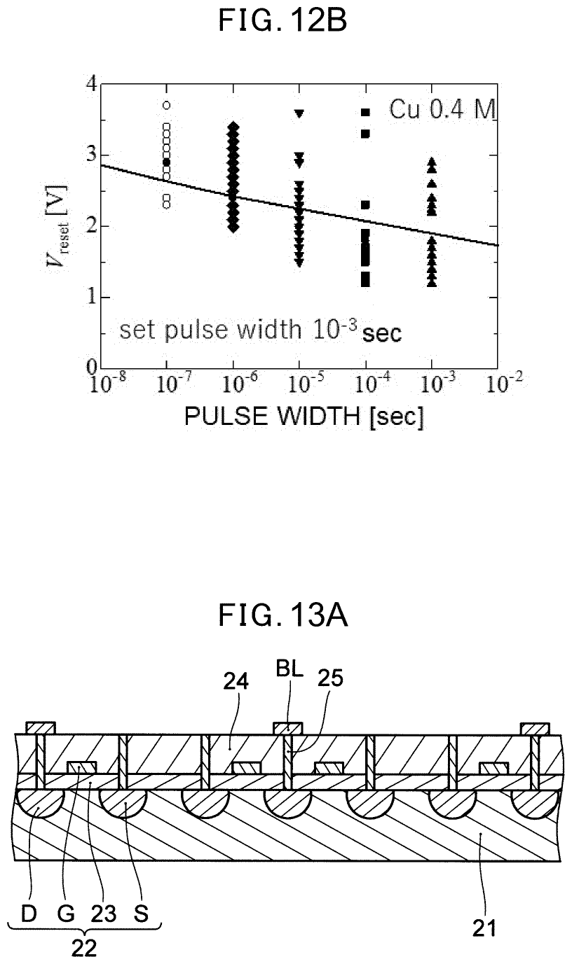

Furthermore, Vₛₑₜ and Vᵣₑₛₑₜ were measured by applying a pulse voltage to the CB-RAM element of Example 4. The measurement results are shown in FIG. 12A for Vₛₑₜ and in FIG. 12B for Vᵣₑₛₑₜ. As shown in FIGS. 12A and 12B, variations in Vₛₑₜ and Vᵣₑₛₑₜ were confirmed to be both approximately 1.5V, the variations being small, even in a case of adopting a pulse voltage.

The present inventors measured the value of current flowing through the CB-RAM elements according to Examples 4 and 5 at a constant time interval by applying a direct current voltage (20 mV) to the CB-RAM elements to confirm changes in the characteristic according to the ion liquid species. In these CB-RAM elements 10 (see FIG. 3B), the first metal layer 11 was set to be Pt having a thickness of 20 nm and the second metal layer 12 was set to be Cu having a thickness of 50 nm, and the liquid layer (Cu 0.4 M and Ag 0.4 M) 14 was set to have a thickness of 30 nm. The measurement results are shown in FIG. 18. As shown in FIG. 18, in this case, in the CB-RAM element according to Example 5, a constant current value could be held for a long time, and a CB-RAM element having a better resistance retaining characteristic could be obtained.

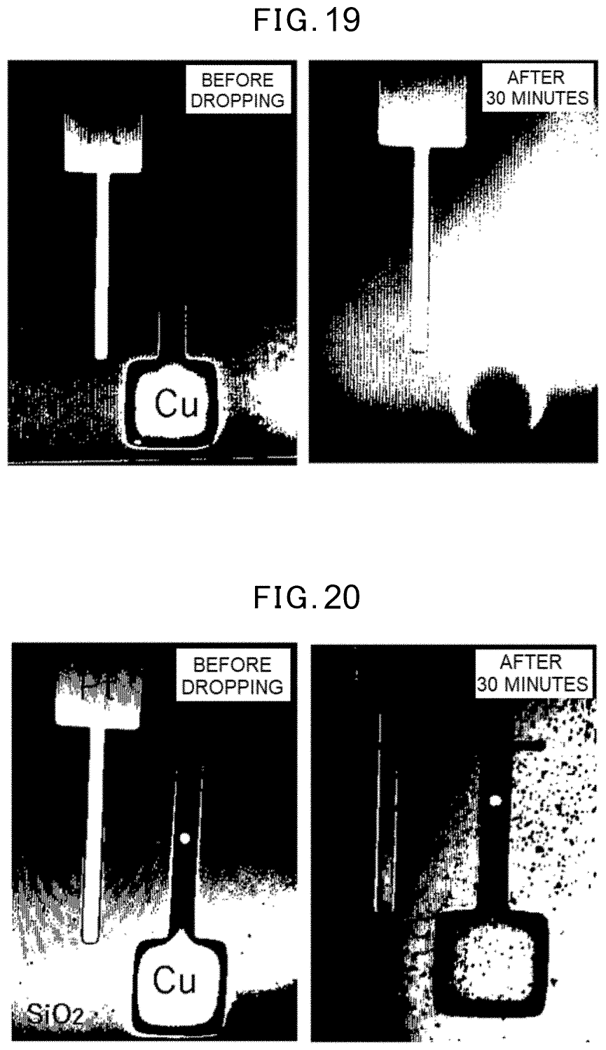

To determine the cause thereof, the present inventors dropped Cu 0.4 M and Ag 0.4 M to a Pt pattern similar to the first metal layer 11 and a Cu pattern similar to the second metal layer 12 and observed, with an optical microscope, the Pt pattern and the Cu pattern before dropping and after dropping (after 30 minutes). Optical microscope images of the Pt pattern and the Cu pattern before and after dropping Cu 0.4 M are shown in FIG. 19 and optical microscope images of the Pt pattern and the Cu pattern before and after dropping Ag 0.4 M are shown in FIG. 20. As shown in FIG. 19, in a case of dropping Cu 0.4 M, no corrosion was observed in the Pt pattern, while corrosion due to dissolution was observed in the Cu pattern. On the other hand, as shown in FIG. 20, in a case of dropping Ag 0.4 M, corrosion was observed in neither the Pt pattern nor the Cu pattern.

In this way, the present inventors have found the Cu pattern being corroded when selecting an ionic liquid containing a divalent Cu ion and the Cu pattern being difficult to corrode when selecting an ionic liquid containing a monovalent Ag ion. Thus, the present inventors focused on an ionic liquid containing, not the divalent Cu ion, but a monovalent Cu ion to investigate an ionic liquid in which the Cu pattern is difficult to corrode, besides the ionic liquid containing the monovalent Ag ion. However, no methods of preparing the ionic liquid containing the monovalent Cu ion were reported. As a result of making intensive studies, as described later (see a fourth embodiment), the present inventors could obtain the ionic liquid containing the monovalent Cu ion using a new manufacturing method of an ionic liquid.

The present inventors observed, with an optical microscope, a Cu pattern after dropping a different plurality of ionic liquids in addition to the obtained ionic liquid containing the monovalent Cu ion. As the ionic liquids, the following seven were used:

Sample 1: [Bmim][TFSA] (the above-described pure)

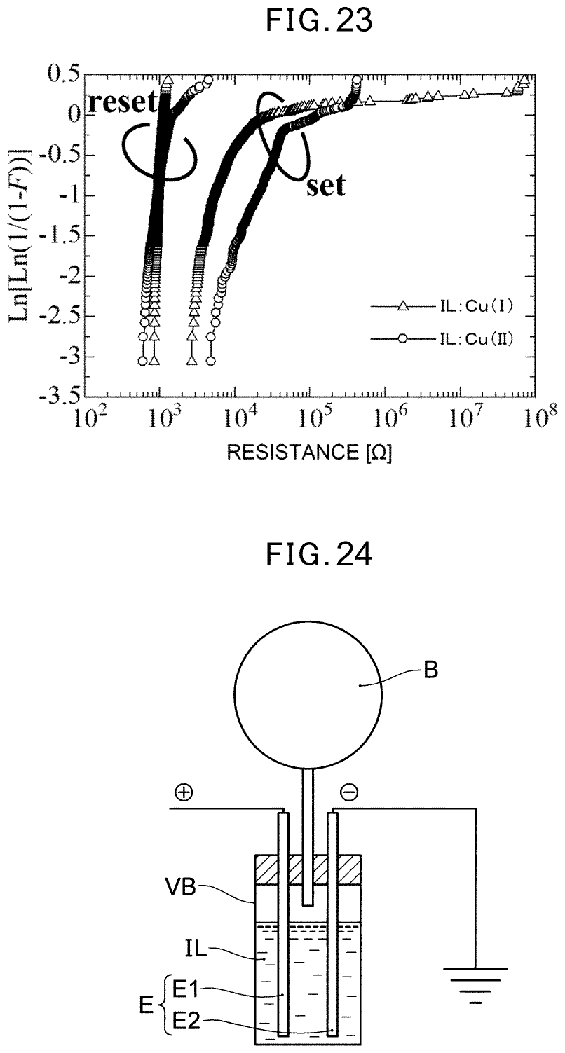

Sample 2: [Bmim][TFSA], in which Cu(II)(TFSA)₂ is dissolved in a saturated state (a 0.4 mol/L concentration) (the above-described Cu 0.4 M; called “Cu(II)” in FIGS. 22 and 23)

Sample 3: [Bmim][TFSA], in which Cu(II)(TFSA)₂ is dissolved in a 0. 4 mol/L concentration and bubbled with an Ar gas

Sample 4: [Bmim][TFSA], in which Ag(I)(TFSA) is dissolved in a 0.4 mol/L concentration (the above-described Ag 0.4 M)

Sample 5: [Bmim][TFSA], in which Cu(I)(TFSA) is dissolved in a saturated state (called “Cu(I)” in FIGS. 22 and 23)

Sample 6: [Bmim][TFSA], in which Cu(I)(FSA) is dissolved. Here, FSA is bis(fluoromethyl)sulfonylamide.

Sample 7: [Bmim][TFSA], in which Cu(I)(TFSA) and Cu(II)(TFSA)₂ are dissolved.

The observation results are shown in Table 1. In the Table, “x”, “Δ”, and “∘” show that the Cu pattern clearly corroded, that the Cu pattern slightly corroded, and that the Cu pattern was not corroded, respectively.

TABLE 1

| Sample No. | 1 | 2 | 3 | 4 | 5 | 6 | 7 |
|---|---|---|---|---|---|---|---|
| Monovalent | — | — | — | Ag⁺ | Cu⁺ | Cu⁺ | Cu⁺ |
| positive ion | | | | | | | |
| Divalent | — | Cu²⁺ | Cu²⁺ | — | — | — | Cu²⁺ |
| positive ion | | | | | | | |
| Dissolution of | x | x | Δ | ∘ | ∘ | ∘ | x |
| Cu pattern | (In the | (In the | (In the | (In the | (In the | (In the | (In the |
| | atmosphere) | atmosphere) | vacuum) | vacuum) | atmosphere) | atmosphere) | atmosphere) |

As shown in Table 1, in a case that an ion liquid of Sample 4, 5, 6 containing only the monovalent Ag ion and Cu ion was used, dissolution of the Cu pattern was not observed. On the other hand, in a case that an ion liquid of Sample 1 not containing a positive ion or Sample 2, 3, 7 containing only the divalent Cu ion was used, dissolution of the Cu pattern was observed. In a case that a test was carried out in Sample 4, not in the vacuum, but in the atmosphere, precipitation of Ag was observed, but dissolution of the Cu pattern was not observed.

Moreover, the present inventors prepared a CB-RAM element according to the above-described second variation of the first aspect, which CB-RAM element includes an ion liquid according to Sample 2 and Sample 5 described above to investigate the impact of the positive ion contained in the ionic liquid on the characteristic of the CB-RAM element.

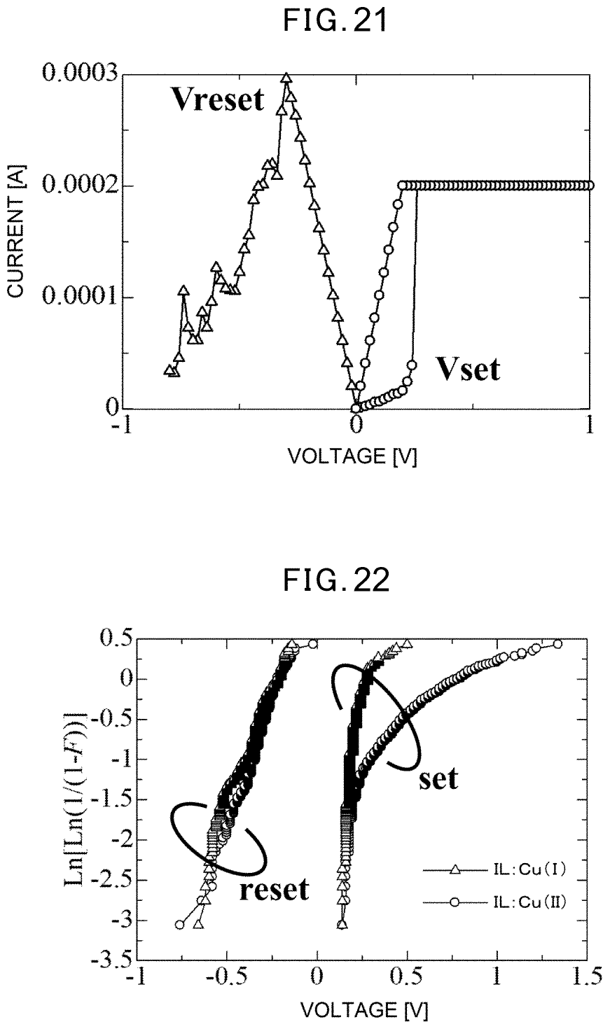

First, a resistance change at the time of applying a predetermined voltage was measured for the CB-RAM element according to Sample 5. The results are shown in FIG. 21. As shown in FIG. 21, even when a monovalent Cu ion was used, in the same manner as a case in which a divalent Cu ion was used, it was confirmed that the resistance of the CB-RAM element could be repeatedly brought to be in a high resistance state and in a low resistance state.

In this way, various characteristics of the CB-RAM element 10 can be controlled by a metal constituting the first metal layer 11 and the second metal layer 12 and the type of positive ion (in particular, the valance number of positive ion) contained in a liquid electrolyte (here, an ionic liquid) constituting the liquid layer 14. This does not depend on whether the insulator layer 13 having the linear-shaped through hole 13h artificially provided is used for the CB-RAM element 10 as in the present embodiment or an insulator layer composed of a porous body in which are included irregular pores in the first place is used for the CB-RAM element as described below (see a third embodiment). In the above-described example, the first metal layer 11 or the second metal layer 12 is composed of Cu. In this case, from a viewpoint of the resistance retaining characteristic, the liquid layer 14 is preferably composed of an ionic liquid containing a monovalent positive ion, or more specifically, an ionic liquid containing a monovalent Cu ion (Cu(I)) or a monovalent Ag ion (Ag(I)).

(Manufacturing Method of CB-RAM Device)

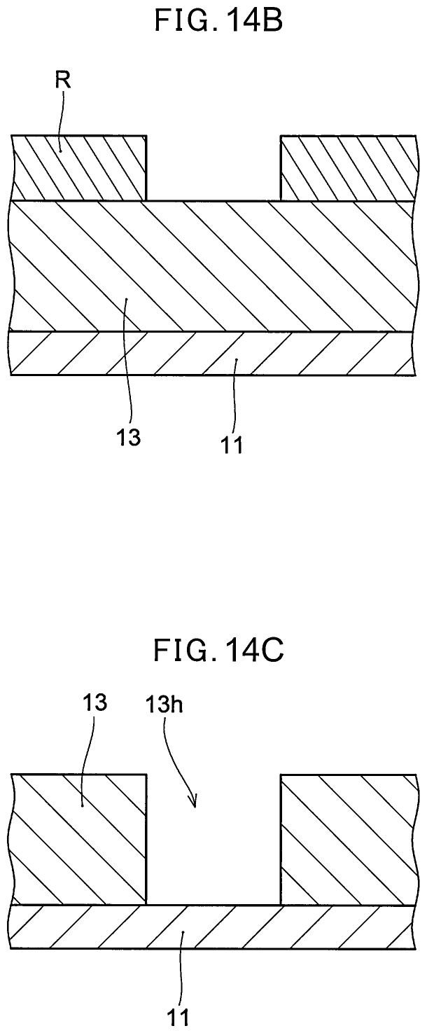

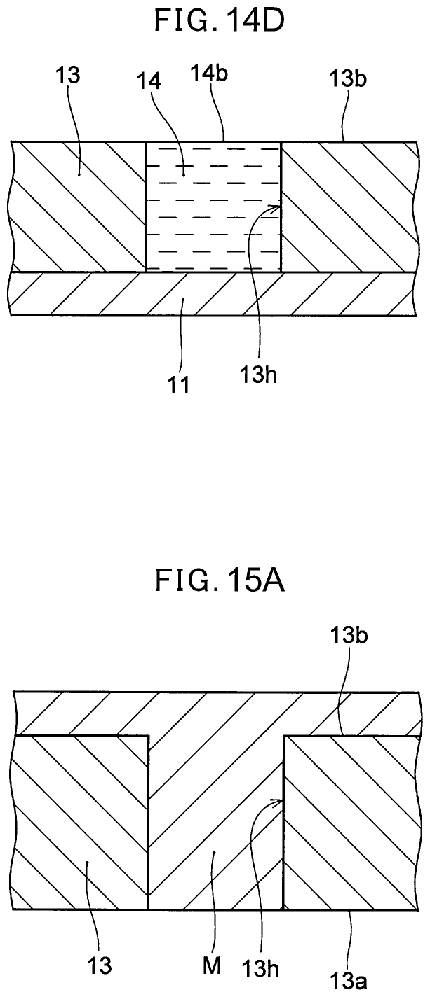

FIGS. 2 to 3C, 7, 13A, 13B, 14A to 14D show a manufacturing process of the CB-RAM device 1 according to the present embodiment. The CB-RAM element 10 included in the CB-RAM device 1 of the present embodiment shown in FIG. 2 corresponds to the above-described first aspect and is manufactured as shown in FIGS. 14A to 14D. First, the insulator layer (the first insulator layer) 13 is formed on a surface of the first metal layer 11, which insulator layer (the first insulator layer) 13 has the first surface (the lower surface) 13a being in contact with the surface and the second surface (the upper surface) 13b being a surface opposite to the first surface (the lower surface) 13a. Next, the through hole 13h penetrating between the first surface (the lower surface) 13a and the second surface (the upper surface) 13b is formed by finely processing the insulator layer (the first insulator layer) 13. Thereafter, the liquid layer 14 being in contact with the first metal layer 11 is provided by impregnating, in the through hole 13h, liquid containing a liquid electrolyte. Next, the second metal layer 12 being in contact with the liquid layer 14 is formed on the second surface (the upper surface) 13b side of the insulator layer (the first insulator layer) 13. Such a manufacturing method of the CB-RAM device 1 will be described in detail below.

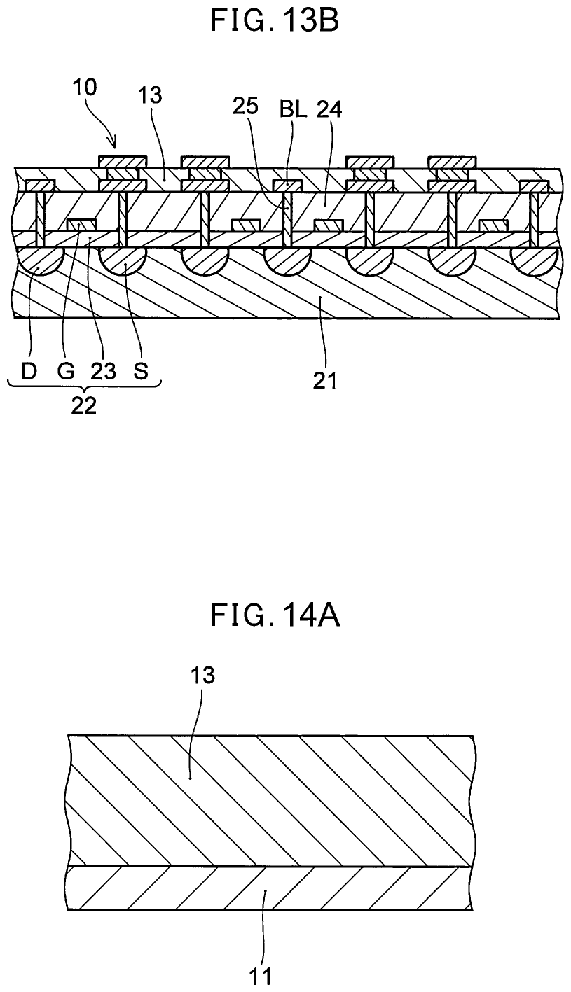

First, as shown in FIG. 13A, the cell selection transistor 22 is formed on a surface of the substrate 21 using a normal semiconductor process, which cell selection transistor 22 has the source 5, the drain D and the gate G, and the gate insulating film 23. Next, the interlayer insulating film 24 is formed over the substrate 21 and the transistor 22, and, thereafter, a through hole exposing a part of the source S and the drain D is provided in the interlayer insulating film 24 and the gate insulating film 23, and the contact plug 25 to fill the through hole is formed. Then, the bit line BL is formed over the contact plug 25 being connected to the drain D.

On the other hand, the CB-RAM element 10 as shown in FIG. 2 is formed over the contact plug 25 being connected to the source S. A manufacturing method of the above-mentioned CB-RAM element 10 will be described below with reference to FIGS. 14A to 14D. First, as shown in FIG. 14A, the first metal layer 11 and the insulator layer (the first insulator layer) 13 of the CB-RAM element 10 are formed in this order as shown in FIG. 14A (In FIGS. 14A to 14D, layers below the first metal layer 11 are omitted for convenience of explanations).

While methods of forming the first metal layer 11 can include a method of depositing a metal such as Pt described above, using a sputtering method, for example, they are not limited thereto. For example, a different method such as a vacuum vapor deposition method can be used. The bit line BL and the first metal layer 11 can be formed simultaneously using the same process. In this case, a metal constituting the bit line BL and that constituting the first metal layer 11 will be the same metal.

While methods of forming the insulator layer (the first insulator layer) 13 can include a method of depositing an insulator such as SiO₂ described above using a CVD (Chemical vapor deposition) method, for example, it is not limited thereto. For example, a different method such as the sputtering method and a sol-gel method can be used.

Thereafter, as shown in FIG. 14B, a resist layer R being patterned in a desired shape is formed by applying a photoresist solution over the insulator layer (the first insulator layer) 13 using a photolithography method to provide the through hole 13h at a desired position of the insulator layer (the first insulator layer) 13, which through hole 13h has a desired size. Next, as shown in FIG. 14C, the through hole 13h is formed in the insulator layer (the first insulator layer) 13 by removing the resist layer R after carrying out anisotropic etching from an opening of the resist layer R.

Next, as shown in FIG. 14D, the liquid layer 14 is provided by supplying the above-described liquid electrolyte to impregnate it in the through hole 13h. Here, while the amount of supplying of the liquid electrolyte is preferably substantially equivalent to the volume of the through hole 13h, it can be within a certain range with respect to the volume of the through hole 13h as in the above-described first to third variations of the present aspect. In other words, the liquid layer 14 can remain in the through hole 13h (see the first variation (FIG. 3A)), can protrude from the through hole 13h (see the second variation (FIG. 3B)), or can leak out not only to the through hole 13h, but also to the upper surface 13b of the insulator layer (the first insulator layer) 13 to cover the upper surface 13b (see the third variation (FIG. 3C)). It has been confirmed that any one of these forms can function as the CB-RAM element 10. With the upper surface 14b of the liquid layer 14 being made to be substantially planar, the upper surface 12b (see FIG. 2) of the second metal layer 12 formed over the liquid layer 14 is also formed to be substantially planar, reflecting the shape of the upper surface 14b of the liquid layer 14. Therefore, there is an advantage of a problem such as an occurrence of a void, disconnection or shorting of a wiring being difficult to occur in a CB-RAM device having a deposition structure (see FIG. 7).

A method of impregnating a liquid electrolyte in the through hole 13h of the insulator layer (the first insulator layer) 13 is not limited in particular. For example, after the tip of a needle-shaped probe is brought into contact with an opening of the through hole 13h after a liquid electrolyte is adhered to the tip of the needle-shaped probe, the liquid electrolyte adhered to the vicinity of the opening of the through hole 13h due to the capillary phenomenon can be impregnated in the through hole 13h. Moreover, after adhering a liquid electrolyte on a surface of the insulator layer (the first insulator layer) 13 using spin coating, PLD (pulse laser ablation), vapor deposition, or inkjet printing, the liquid electrolyte adhered to the vicinity of the opening of the through hole 13h due to the capillary phenomenon can be impregnated in the through hole 13h. Furthermore, methods of making the upper surface 14b of the liquid layer 14 substantially planar can include, for example, a method of applying a liquid electrolyte using spin coating, and, thereafter, removing a liquid electrolyte exceeding the volume of the through hole 13h by increasing the rotating speed of spin coating.

Next, forming of the CB-RAM element 10 is completed by forming the second metal layer 12 so as to cover the liquid layer 14 as shown in FIGS. 2 to 3C (see also FIG. 13B). While methods of forming the second metal layer 12 can include a method of depositing a metal such as Cu described above, using the sputtering method, for example, it is not limited thereto. For example, a different method such as the vacuum vapor deposition method can be used. Here, the second metal layer 12 is preferably formed using a method in which metal ions of the liquid layer 14 do not aggregate by a metal material of the second metal layer 12 dissolving in the liquid layer 14, or the liquid layer 14 being exposed to the formed atmosphere of the second metal layer 12.

Next, the interlayer insulating film 27 is formed over the CB-RAM element 10 (the insulator 13 of the CB-RAM element 10 and the above-mentioned interlayer insulating film 27 are suitably integrated), and, thereafter, a through hole exposing a part of the second metal layer 12 of the CB-RAM element 10 is provided in the interlayer insulating film 27. Then, the contact plug 28 to fill the through hole is formed, and thereafter, the source line SL is formed over the contact plug 28. In this way, the CB-RAM device 1 of the present embodiment shown in FIG. 7 is completed.

In this way, in the CB-RAM device 1 of the present embodiment, the through hole 13h is accurately formed in the insulator layer (the first insulator layer) 13 of the CB-RAM element using a photolithography method, which through hole 13h penetrates between the first metal layer 11 and the second metal layer 12. Providing the through hole 13h in this way was found to allow suppressing variations of the operation characteristic of the CB-RAM device as described above.

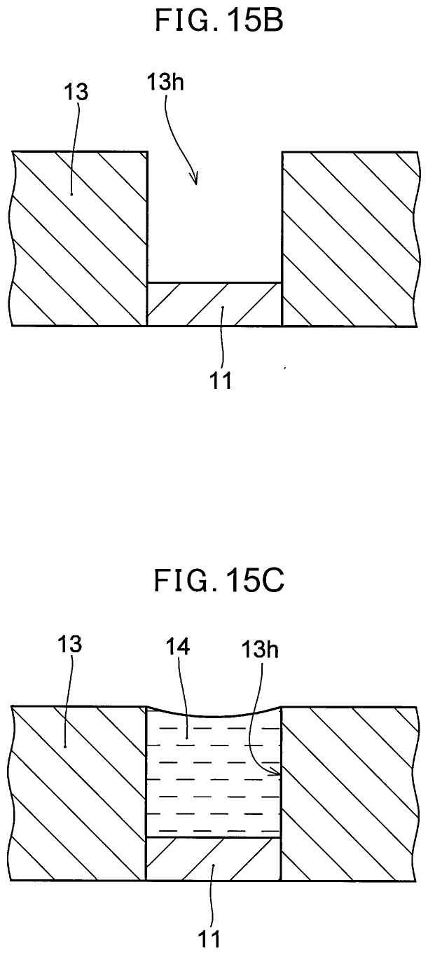

Moreover, in the above-described second aspect, the CB-RAM element 10 shown in FIG. 4 is formed over the contact plug 25 connected to the source S shown in FIG. 13A. First, the through hole 13h penetrating between the first surface (the lower surface) 13a and the second surface (the upper surface) 13b is formed by forming the insulator layer (the first insulator layer) 13 having the first surface (the lower surface) 13a and the second surface (the upper surface) 13b being a surface opposite thereto and finely processing the insulator layer (the first insulator layer) 13. Next, the first metal layer 11 is embedded in a part in the through hole 13h. Thereafter, the liquid layer 14 being in contact with the first metal layer 11 is provided by impregnating liquid containing a liquid electrolyte in the through hole 13h in which the first metal layer 11 is embedded. Thereafter, the second metal layer 12 being in contact with the liquid layer 14 is formed on the second surface (upper surface) 13b side of the insulator layer (the first insulator layer) 13. In other words, in the second aspect, that the first metal layer 11 is embedded in a part in the through hole 13h is different in comparison to the first aspect. A manufacturing method of the CB-RAM element 10 included in the CB-RAM device 1 shown in FIG. 4 as such will be described in detail below with reference to FIGS. 15A to 15C.

First, as shown in FIG. 15A, the insulator layer (the first insulator layer) 13 is formed over the interlayer insulating film 24 (see FIG. 13A), and, thereafter, the through hole 13h penetrating between the lower surface 13a and the upper surface 13b thereof is provided by isotropic etching using a photolithography method. While not illustrated here, the above-mentioned through hole 13h is provided so as to expose the contact plug 25 (see FIG. 13A) being connected to the source S of the cell selection transistor 22. Next, a metal M constituting the first metal layer 11 such as Pt described above is deposited on the upper surface 13b of the insulator layer (the first insulator layer) 13 and in the interior of the through hole 13h. Thereafter, as shown in FIG. 15B, the deposited metal M is etched back by carrying out anisotropic etching to form the first metal layer 11 being embedded in the through hole 13h. Next, as shown in FIG. 15C, the liquid layer 14 is formed by impregnating a liquid electrolyte in a remaining space of the through hole 13h using a technique similar to that in the above-described embodiment. Finally, the CB-RAM element 10 is completed by forming the second metal layer 12 so as to cover the liquid layer 14 using a technique similar to that for the above-described embodiment. While the second metal layer 12 is formed on the upper surface 13b of the insulator layer (the first insulator layer) 13 in FIG. 4, the liquid layer 14 can be interposed between the upper surface 13b of the insulator layer (the first insulator layer) 13 and the lower surface 12a of the second metal layer 12 in the same manner as in the above-described third aspect.

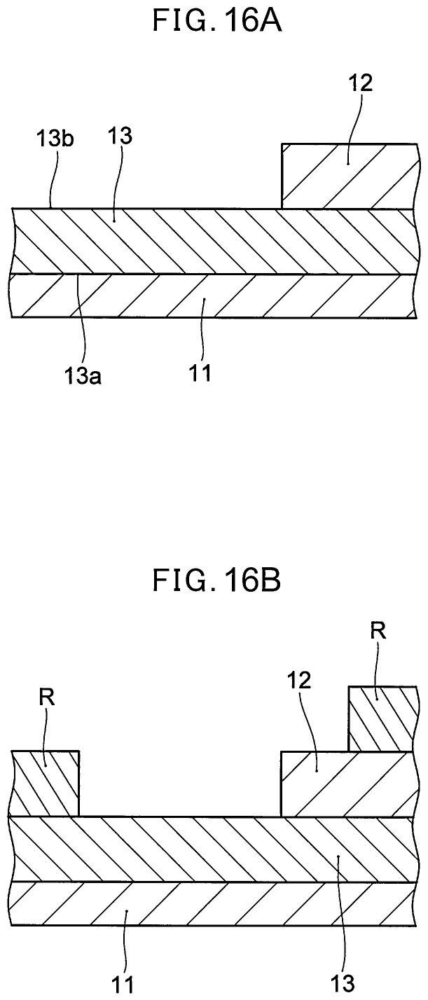

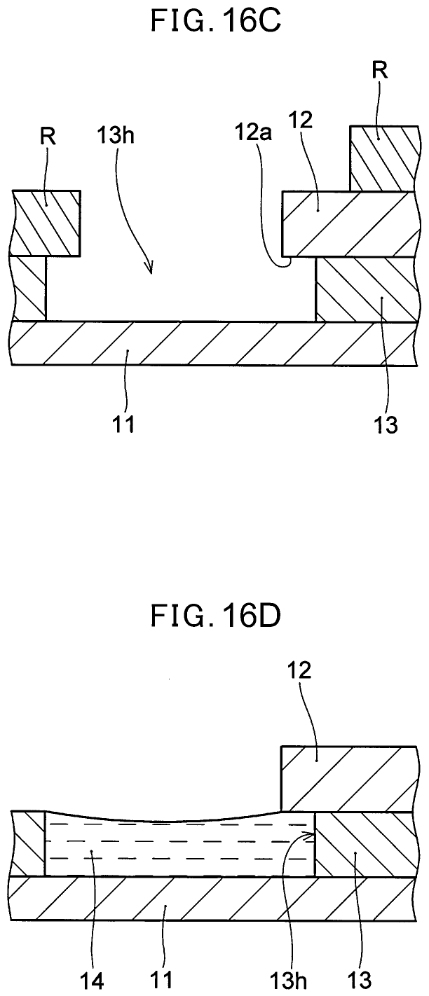

Moreover, in the above-described third aspect, the CB-RAM element 10 shown in FIG. 5 is formed over the contact plug 25 being connected to the source S shown in FIG. 13A. First, the insulator layer (the first insulator layer) 13 is formed on a surface of the first metal layer 11, which insulator layer (the first insulator layer) 13 has the first surface (the lower surface) 13a being in contact with the surface and the second surface (the upper surface) 13b being a surface opposite thereto, and the second metal layer 12 is formed on a part of the second surface (the upper surface) 13b of the insulator layer (the first insulator layer) 13. Next, the through hole 13h penetrating between the first surface (the lower surface) 13a and the second surface (the upper surface) 13b, a part of which through hole 13h is covered by the second metal layer 12, is formed by finely processing the insulator layer (the first insulator layer) 13, and the first metal layer 11, and the liquid layer 14 being in contact with the first metal layer 12 are provided by impregnating, in the through hole 13h, liquid containing a liquid electrolyte. Thereafter, the insulator layer (the second insulator layer) 15 is formed on the second surface (the upper surface) 13b side of the insulator layer (the first insulator layer) 13 so as to cover the second metal layer 12 and the liquid layer 14 being exposed. In other words, the third aspect is different in comparison to the above-described aspect in forming the through hole 13h in the insulator layer (the first insulator layer) 13 after forming the second metal layer 12. A manufacturing method of the CB-RAM element 10 included in the CB-RAM device 1 shown in FIG. 5 as such will be described in detail below with reference to FIGS. 16A to 16D.

First, as shown in FIG. 16A, in the same manner as the above-described aspect, the first metal layer 11 and the insulator layer (the first insulator layer) 13 of the CB-RAM element 10 are formed in this order. Thereafter, unlike the above-described aspect, the second metal layer 12 being patterned is formed. While a method of forming the second metal layer 12 is not particularly limited, with a metal material of the second metal layer 12, such as Pt described above, being deposited on a surface of the insulator layer (the first insulator layer) 13 using the sputtering method, for example, thereafter, the second metal layer 12 can be formed by patterning the deposited metal using the photolithography method.

Next, as shown in FIG. 16B, the resist layer R being patterned in a desired shape is formed on a surface of the insulator layer (the first insulator layer) 13 and the second metal layer 12 by applying a photoresist solution thereto to expose it using the photolithography method. Then, as shown in FIG. 16C, after isotropic etching is carried out from an opening of the resist layer R, the through hole 13h is formed in the insulator layer (the first insulator layer) 13. At this time, an undercut is formed below the insulator layer (the first insulator layer) 13 such that a part of the lower surface 12a of the second metal layer 12 is exposed using isotropic etching, so that the through hole 13h extends between the second metal layer 12 and the first metal layer 11.

Next, as shown in FIG. 16D, the resist layer R is removed, and, thereafter, a liquid electrolyte is impregnated in the through hole 13h to form the liquid layer 14 using a technique being similar to that for the above-described embodiment. Finally, the CB-RAM element 10 is completed by forming the insulator layer (the second insulator layer) 15 so as to cover the liquid layer 14 (the through hole 13h) as shown in FIG. 5. While the second metal layer 12 is formed on the upper surface 12b of the second metal layer 12B and the upper surface 13b of the insulator layer (the first insulator layer) 13 in FIG. 5, the liquid layer 14 can be interposed between at least one of the upper surface 12b of the second metal layer 12B and the upper surface 13b of the insulator layer (the first insulator layer) 13, and the lower surface 15a of the insulator layer (the second insulator layer) 15.

According to the present aspect, the second metal layer 12 has already been formed before forming the liquid layer 14. At the time of forming the metal layer, a material constituting the metal layer can dissolve in the liquid electrolyte depending on the film forming method, selection of the film forming device, or film forming conditions in the above-mentioned film forming device. Moreover, metal ions in the liquid electrolyte can aggregate by the liquid electrolyte being exposed to plasma of a process gas used in film forming. In this way, the liquid electrolyte being affected by a forming process of the second metal layer can also adversely affect the operation characteristic of the CB-RAM element. On the contrary, in the present aspect, there is an advantage that the liquid layer 14 is not adversely affected by the forming process of the second metal layer 12 since the liquid layer 14 has not been formed yet at the time of forming the second metal layer 12.

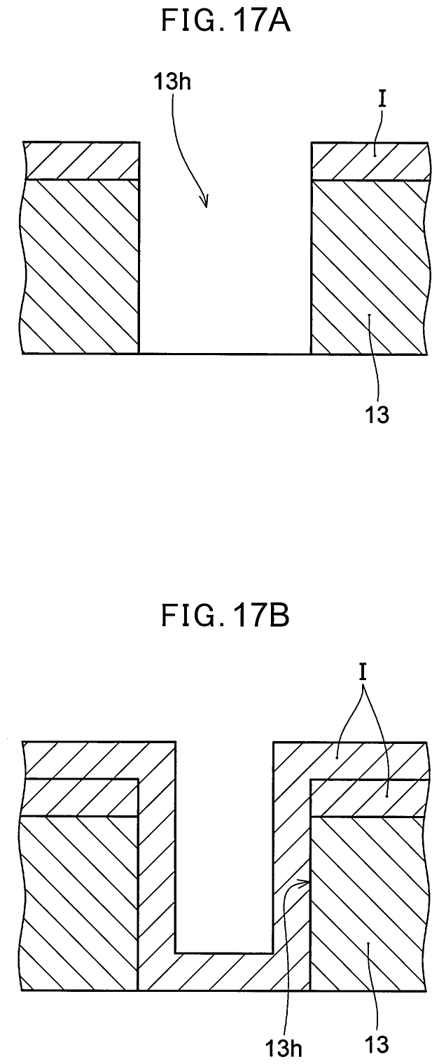

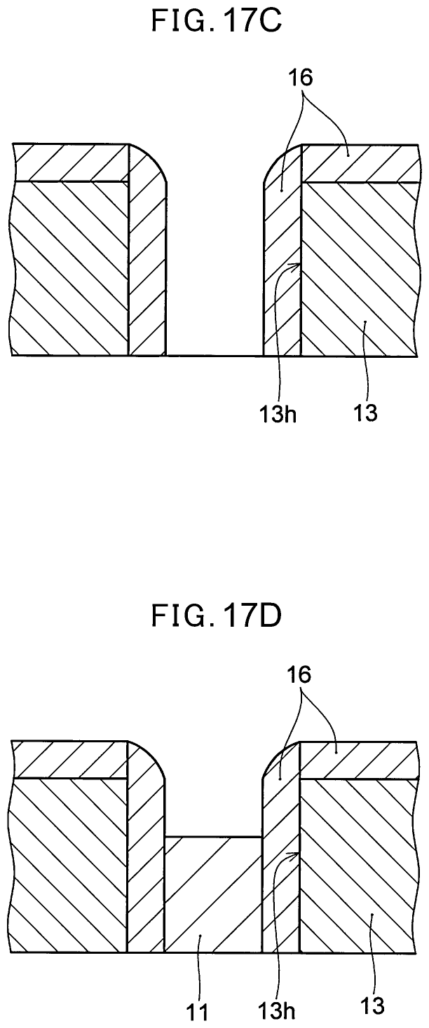

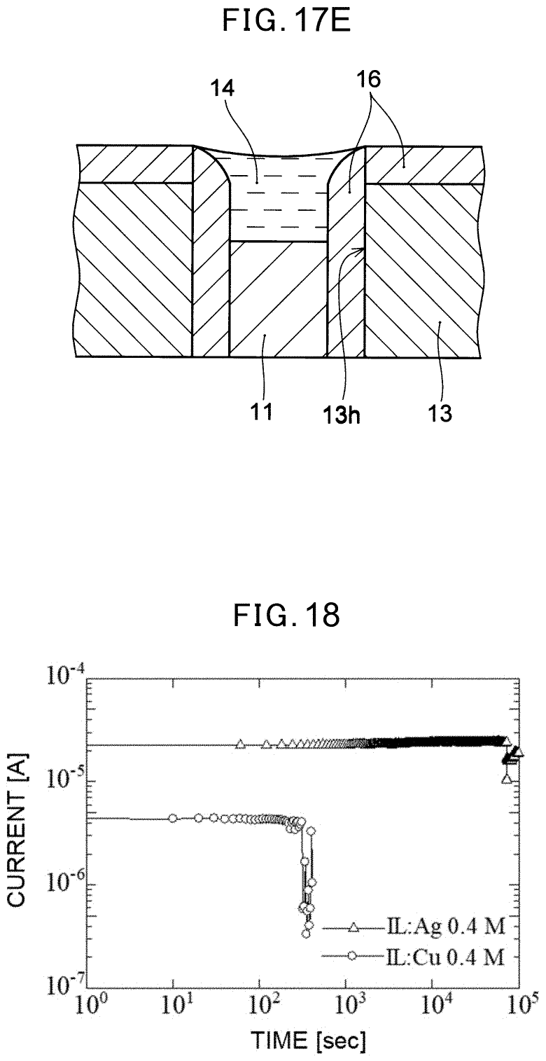

Moreover, in the above-described fourth aspect, the CB-RAM element 10 shown in FIG. 6 is formed over the contact plug 25 connected to the source S shown in FIG. 13A. First, the through hole 13h is formed in the insulator layer (the first insulator layer) 13, and then a different insulator layer (a third insulator layer) 16 being higher in wettability of the liquid electrolyte than the insulator layer (the first insulator layer) 13 is formed on the inner wall of the through hole 13h, and the liquid layer 14 is formed by impregnating the liquid electrolyte in the through hole 13h surrounded by the insulator layer (the third insulator layer) 16. In other words, the fourth embodiment differs in that the different insulator layer (the third insulator layer) 16 being higher in wettability of the liquid electrolyte than the insulator layer (the first insulator layer) 13 is formed on the inner wall of the through hole 13h. A manufacturing method of the CB-RAM element 10 included in the CB-RAM device 1 shown in FIG. 6 as such will be described in detail with reference to FIGS. 17A to 17E.

First, as shown in FIG. 17A, in the same manner as the above-described second aspect, the insulator layer (the first insulator layer) 13 is formed over the interlayer insulating film 24 (see FIG. 14A), and, thereafter, an insulator I being different from an insulator constituting the insulator layer (the first insulator layer) 13 is deposited on a surface of the insulator layer (the first insulator layer) 13 using a CVD method, for example. The insulator I to be the insulator layer (the third insulator layer) 16 (see FIG. 17C) is selected in advance from a material being better in the wettability to the liquid electrolyte than an insulating material constituting the insulator layer (the first insulator layer) 13 by matching with the liquid electrolyte used as described above. Next, the through hole 13h is provided in the insulator layer (the first insulator layer) 13 and the deposited insulator I by etching using the photolithography method, for example, and, thereafter, as shown in FIG. 17B, the insulator I is further deposited on the inner wall of the through hole 13h and on a surface of the insulator I using an isotropic deposition technique such as atomic layer deposition (ALD), for example. Then, as shown in FIG. 17C, the insulator layer (the third insulator layer) 16 is formed by removing the insulator I above the insulator layer (the first insulator layer) 13 and at the bottom of the through hole 13h. In this way, the through hole 13h is surrounded by the insulator layer (the third insulator layer) 16 being different from the insulator layer (the first insulator layer) 13.

Next, as shown in FIG. 17D, using a technique (see FIGS. 15A and 15B) in the same manner as the above-described second aspect, the first metal layer 11 being embedded in the through hole 13h is formed. Thereafter, as shown in FIG. 17E, using a technique being similar to the above-described embodiment, the liquid layer 14 is formed by impregnating the liquid electrolyte in the remaining space of the through hole 13h. At this time, the through hole 13h is brought into contact with the insulator layer (the third insulator layer) 16 having a better wettability to the liquid electrolyte than that of the insulator layer (the first insulator layer) 13, making it possible to easily impregnate the liquid electrolyte in the through hole 13h. Finally, the CB-RAM element 10 is completed by forming the second metal layer 12 so as to cover the liquid layer 14 as shown in FIG. 6. While the second metal layer 12 is formed on the upper surface 16b of the insulator layer (the third insulator layer) 16 in FIG. 6, the liquid layer 14 can be interposed between the upper surface 16b of the insulator layer (the third insulator layer) 16 and the lower surface 12a of the second metal layer 12.

According to the CB-RAM device 1 in the present embodiment, which CB-RAM device 1 is configured as in the above, the through hole 13h is formed in the first insulator layer 13, so that the liquid layer 14 impregnated in the through hole 13h is easily connected reliably between the first metal layer 11 and the second metal layer 12. As a result, the through hole 13h can be made thin, making it possible to realize a further minituarization. Moreover, infiltration of liquid into the through hole 13h can also be easily carried out, making it possible to substantially shorten the manufacturing process.

Moreover, controlling the position, size, shape, and density of the through hole 13h is made possible, making it possible to suppress variations in the operation characteristic such as an operating voltage of the CB-RAM device 1. In particular, there is an advantage that variations in the operation characteristic are suppressed even when a further minituarization of elements is achieved, making preparation of the CB-RAM device 1 having a stable performance possible.

### Second Embodiment

### (Structure of Switching Element)

The CB-RAM element 10 according to the first embodiment can also be used as a switching element, so that a CB-RAM device comprising the CB-RAM element 10 according to the first embodiment can also be applied to a switching device. In applying to the switching device, the cross-sectional structure of the CB-RAM device is not limited to the cross-sectional structure of FIG. 7, so that an appropriate existing structure can be adopted to perform a switching operation, and, for a circuit configuration of the CB-RAM device, an appropriate existing circuit configuration to perform the switching operation can be adopted. In other words, as shown in FIG. 2 with a structure of one example thereof, for example, the switching device comprises a switching element 10 including: a first metal layer 11 (an electrode A); a second metal layer 12 (an electrode B); an insulator layer 13 having a lower surface (a first surface) 13a facing the first metal layer 11 and an upper surface (a second surface) 13b facing the second metal layer 12 and being a surface opposite to the lower surface (the first surface) 13a, and having a through hole 13h penetrating between the lower surface (the first surface) 13a and the upper surface (second surface) 13b; and a liquid layer 14 being formed of liquid containing a liquid electrolyte impregnated in the through hole 13h. Then, the above-mentioned switching device 1 performs an electrical switching operation by electrical resistance between the first metal layer 11 and the second metal layer 12 changing to either a high resistance or a low resistance due to a change in voltage applied between the first metal layer 11 and the second metal layer 12.

### Third Embodiment

As described above, various characteristics of the CB-RAM element can also be controlled by a metal constituting the first metal layer 11 and the second metal layer 12 and the type of positive ion (in particular, the valance number of positive ion) contained in a liquid electrolyte (here, an ionic liquid) constituting the liquid layer 14. This does not depend on whether the insulator layer 13 having the linear-shaped through hole 13h artificially provided is used for the CB-RAM element 10 as in the first to second embodiments or an insulator layer composed of a porous body in which are included irregular pores in the first place is used for the CB-RAM element. In the above-described example, the first metal layer 11 or the second metal layer 12 is composed of Cu. In this case, from a viewpoint of the resistance retaining characteristic, the liquid layer 14 is preferably composed of an ionic liquid containing a monovalent positive ion, or more specifically, an ionic liquid containing a monovalent Cu ion (Cu(I)) or a monovalent Ag ion (Ag(I)).

In other words, a conductive bridge memory device according to the present embodiment is a conductive bridge memory device comprising a memory cell including: a first metal layer 11; a second metal layer 12; an insulator layer 13 being arranged between the first metal layer 11 and the second metal layer 12, which insulator layer 13 has a first surface 13a facing the first metal layer 11 and a second surface 13b facing the second metal layer 12 and being a surface opposite to the first surface 13a and has a communicatively connecting hole communicatively connecting between the first surface 13a and the second surface 13b; and a liquid layer 14 being formed of liquid containing a liquid electrolyte impregnated in the communicatively connecting hole, wherein the first metal layer 11 or the second metal layer 12 preferably contains Cu, and the liquid (preferably an ionic liquid) containing a monovalent positive ion (preferably a monovalent Cu ion and/or a monovalent Ag ion) makes it possible to suppress corrosion of Cu constituting the first metal layer 11 or the second metal layer 12, and, moreover, makes it possible to suppress also variations in any one of Vₛₑₜ and Vᵣₑₛₑₜ and R_{HRS} and R_{LRS}. Here, “communicatively connecting” refers to an air gap being formed in an arbitrary form so as to connect between the first surface 13a and the second surface 13b of the insulator layer 13. That is, with the “communicatively connecting”, an air gap connecting between the first surface 13a and the second surface 13b can be formed, for example, regularly as in a linear shape, or formed irregularly as pores included in the porous body. In other words, the “communicatively connecting” refers to the fact that a liquid impregnated in the insulator layer 13 can be connected between the first surface 13a and the second surface 13b. The porous body having the pores as such can be composed of HfO₂, SiO₂, AL₂O₃, GeSe, or AgS₂, for example.

### Fourth Embodiment

As a liquid electrolyte (here, an ionic liquid) in which the Cu pattern is difficult to corrode, the present inventors focused on a liquid electrolyte containing a monovalent Cu ion. However, no methods of obtaining the liquid electrolyte containing the monovalent Cu ion were found. As a result of making intensive studies, the present inventors could obtain the liquid electrolyte containing the monovalent Cu ion using a new manufacturing method of a liquid electrolyte shown below. In the present embodiment, a new manufacturing method with respect to a liquid electrolyte containing a monovalent Cu ion will be described with reference to FIG. 24. While the liquid electrolyte containing the monovalent Cu ion obtained with the manufacturing method according to the present embodiment can be used suitably as a material constituting the liquid layer 14 of the CB-RAM element 10 according to the first to third embodiments, the use thereof is not particularly limited, so that it can be applied to an arbitrary use such as an arbitrary CB-RAM element using an ionic liquid as a liquid electrolyte.

First, in the atmosphere not containing oxygen, a liquid electrolyte IL containing an imidazolium salt is brought into contact with one pair of electrodes E. One electrode of the one pair of electrodes E used is formed so as to contain Cu. In the present embodiment, the atmosphere not containing oxygen was formed by making a fluid connection of an Ar-filled balloon B to a vial tube VB and replacing the atmosphere in the vial tube VB with Ar. However, a method of forming the atmosphere not containing oxygen is not particularly limited thereto, so that the above-mentioned atmosphere can be formed using a different means such as a vacuum chamber. Moreover, the atmospheric gas is not limited to Ar, so that it can be an inert gas such as N₂ or a different noble gas. In the present embodiment, 10 ml of [Bmim][TFSA] was injected in the vial tube VB as the liquid electrolyte IL, and was brought into contact with the one pair of electrodes E with an anode E1 being composed of Cu and a cathode E2 being composed of Pt. However, the liquid electrolyte IL is not particularly limited thereto as long as it is a liquid electrolyte containing an imidazolium salt, so that it can be a different liquid electrolyte such as an ionic liquid containing an imidazolium cation other than [Bmim] being shown in the above-described Chemical formulas [3] and [4]. Moreover, the amount of the above-mentioned liquid electrolyte IL is appropriately changed as needed. Furthermore, the one pair of electrodes E is not particularly limited thereto as long as one electrode thereof contains Cu, so that it can be selected from a different combination, including being selected from a combination of metals listed as a material for the first metal layer 11 and the second metal layer 12 described above, for example.

Thereafter, a predetermined voltage is applied to the one pair of electrodes E. The applying of the voltage is preferably carried out until current ceases to flow through the one pair of electrodes E. In this way, it is believed that the liquid electrolyte IL in which the monovalent Cu ion is contained in a saturated state can be obtained. In the present embodiment, a voltage of 3.8 V was applied to the one pair of electrodes E. In this way, the anode E1 eluted and also H₂ was produced from the cathode E2, the above-mentioned liquid electrolyte IL gradually turned to a dark brown color, and then Cu precipitated in a dendritic shape in the cathode E2. The applying of the voltage to the one pair of electrodes E was carried out until current ceased to flow through the one pair of electrodes E. A monovalent Cu ion was detected from the liquid electrode IL after current flowed therethrough. In the present embodiment, the following electrochemical reaction is believed to have proceeded:

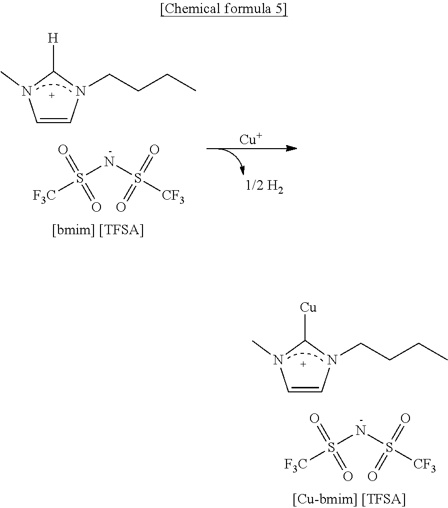

While a voltage of 3.8 V was applied to the one pair of electrodes E in the present embodiment, the voltage to be applied to the one pair of electrodes E is not particularly limited thereto as long as the above-described electrochemical reaction of the liquid electrolyte IL proceeds, so that it can be a voltage being greater or less there than.

A liquid electrolyte containing a monovalent Cu ion could be obtained using the process in the above. In the present embodiment, it is believed that a liquid electrolyte IL with a monovalent Cu ion being dissolved in a saturated state was obtained since application of a voltage to the one pair of electrodes E was carried out until current ceased to flow therethrough.

According to the liquid electrolyte IL obtained by a manufacturing method according to the present embodiment, as described above, corrosion of the Cu pattern being suppressed, and variations in any one of Vₛₑₜ and Vᵣₑₛₑₜ and R_{HRS} and R_{LRS} being less in a CB-RAM element using the above-described liquid electrolyte IL as a liquid layer than in a CB-RAM element using a liquid electrolyte containing a divalent Cu ion as a liquid layer were confirmed. Moreover, when operated with the same operating pattern, the resistance retaining characteristic being more superior in a CB-RAM element using the liquid electrolyte IL containing a monovalent Cu ion as a liquid layer than in a CB-RAM element using a liquid electrolyte containing a divalent Cu ion as a liquid layer was confirmed.

While embodiments of the present disclosure have been described in the above, a material for an electrode, a liquid electrolyte, and an insulator layer can be modified or changed as needed in accordance with the common general technical knowledge of a person skilled in the art. Moreover, while exemplary applications of the present disclosure to a memory element and a switching element have been shown in the above-described embodiments, the present disclosure is not particularly limited thereto, so that it can be applied to various devices.

### CONCLUSION

A conductive bridge memory device according to one embodiment of the present disclosure comprises: a memory cell including a first metal layer; a second metal layer; a first insulator layer having a first surface facing the first metal layer and a second surface facing the second metal layer and being a surface opposite to the first surface, and having a through hole penetrating between the first surface and the second surface; and a liquid layer being formed of liquid containing a liquid electrolyte impregnated in the through hole.

According to one embodiment of the present disclosure, a through hole penetrating between a first surface and a second surface, not pores in which the position, size, shape, and density are random as in a porous body, is provided in a first insulator layer, making it possible to suppress variations in the operation characteristic of a conductive bridge memory device.

A metal constituting the second metal layer can be formed of a metal being different from a metal constituting the first metal layer in electrochemical activity. Such a configuration allows easily forming a filament-like conductive path in a through hole, improving the resistive switching characteristic of a conductive bridge memory device.

The through hole has a tapered shape in which a size of an opening facing the first metal layer and a size of an opening facing the second metal layer can be substantially the same, or a size of either one opening can be greater than a size of the other opening. Such a configuration makes it possible to obtain an optimal through hole.

The through hole can be a finely processed hole. According to such a configuration, the through hole is formed by fine processing, making it possible to set the position, size, shape, and density of the through hole as desired.

The through hole can be formed in one to five for the memory cell. Such a configuration makes it possible to form a fine memory cell since the through hole provided for the memory cell is in a very small amount.

The through hole can be formed in one for the memory cell. Such a configuration makes it possible to form a finer memory cell since the through hole provided for the memory cell is formed in one.

The liquid layer can contain an ionic liquid. Such a configuration makes it possible to design a conductive bridge memory device being stable and having a high performance.

The ionic liquid can contain a mixed ionic liquid in which are mixed a solvated ionic liquid, and a low-viscosity ionic liquid being an ionic liquid having a viscosity coefficient smaller than that of the solvated ionic liquid. Such a configuration makes it possible to design a conductive bridge memory device being more stable and having a higher performance.

A size of the through hole can be greater than or equal to 5 nm and less than or equal to 1000 nm. Such a configuration makes it possible to obtain an optimal through hole.

A shape of the through hole in planar view can be a shape being closed with a straight line, a curve, or both thereof, in which shape can be drawn a circle to be included. Such a configuration makes it possible to obtain a through hole in an optimal shape from a variety of shapes.

The first insulator layer can be formed of an amorphous body. Such a configuration makes it possible to obtain a first insulator layer formed of only a through hole, which first insulator layer has no pores.

A part or a whole of the first metal layer can be embedded in a part of the through hole; and the liquid layer can be provided in the through hole between the first metal layer embedded therein and the second metal layer. Such a configuration makes it possible to obtain a finer conductive bridge memory device since an operating area is specified by only a forming area of a fine through hole.

The second metal layer can be formed so as to cover a part of the liquid layer; and a second insulator layer can be formed so as to cover the second metal layer, and the liquid layer not covered by the second metal layer. Such a configuration allows an operating area to be defined by an area between a first metal layer and a second metal layer. Moreover, it allows the element structure to be easily miniaturized.

An inner wall of the through hole can be covered with a third insulator to which a wettability of the liquid is higher than that to the first insulator layer; and the liquid layer can be provided in the through hole surrounded by the third insulator layer. Such a configuration makes it possible to easily impregnate liquid in the through hole.

The liquid layer can be interposed between the second metal layer, and the second surface of the first insulator layer. Such a configuration can function as a conductive bridge memory device even when a liquid layer is interposed between a second metal layer, and a second surface of an insulator layer.

The first metal layer or the second metal layer can be composed of a plurality of layers; the first metal layer or the second metal layer can include a first layer being in contact with the liquid layer of the plurality of layers and a second layer provided opposite to the liquid layer with respect to the first layer; and the second layer can function as a cap layer to prevent oxidation of the first layer being an electrode layer to deliver and receive charges with the liquid layer. Such a configuration makes it possible to prevent, even when a layer being on the side being in contact with a liquid layer is composed of a material being easily oxidized, oxidation of the above-mentioned layer.

The cap layer, the cap layer can contain at least one type of metal to be selected from a group consisting of Au, Ni, Ta, Nb, W, Pt, and Mo. Such a configuration makes it possible to effectively make full use of the function as a cap layer.

A switching device according to one embodiment of the present disclosure comprises a switching element including a first metal layer; a second metal layer; a first insulator layer having a first surface facing the first metal layer and a second surface facing the second metal layer and being a surface opposite to the first surface, and having a through hole penetrating between the first surface and the second surface; and a liquid layer being formed of liquid containing a liquid electrolyte impregnated in the through hole, wherein the switching device performs an electrical switching operation by electrical resistance between the first metal layer and the second metal layer changing to either a high resistance or a low resistance due to a change in voltage applied between the first metal layer and the second metal layer.

According to one embodiment of the present disclosure, a through hole penetrating between a first surface and a second surface, not pores in which the position, size, shape, and density are random as in a porous body, is provided in a first insulator layer, making it possible to suppress variations in the operation characteristic of a switching device.

A manufacturing method of a conductive bridge memory device according to one embodiment of the present disclosure includes: forming, on a surface of a first metal layer, a first insulator layer having a first surface being in contact with the surface and a second surface being a surface opposite to the first surface; forming a through hole penetrating between the first surface and the second surface by finely processing the first insulator layer; providing a liquid layer being in contact with the first metal layer by impregnating, in the through hole, liquid containing a liquid electrolyte; and forming, on the second surface side of the first insulator layer, a second metal layer being in contact with the liquid layer.

According to one embodiment of the present disclosure, a through hole penetrating between a first surface and a second surface, not pores in which the position, size, shape, and density are random as in a porous body, is provided in a first insulator layer, making it possible to suppress variations in the operation characteristic of a conductive bridge memory device.

Moreover, a manufacturing method according to one variation of one embodiment includes: forming a first insulator layer having a first surface, and a second surface being a surface opposite to the first surface; forming a through hole penetrating between the first surface and the second surface by finely processing the first insulator layer; embedding a first metal layer in a part in the through hole; providing a liquid layer being in contact with the first metal layer by impregnating, in the through hole in which the first metal layer is embedded, liquid containing a liquid electrolyte; and forming, on the second surface side of the first insulator layer, a second metal layer being in contact with the liquid layer.

According to such a configuration, a first metal layer is embedded in a part in a through hole, making it possible to form a fine element, and, thus, to contribute to downsizing of a conductive bridge memory device.

Moreover, a manufacturing method according to another variation of one embodiment includes: forming, on a surface of a first metal layer, a first insulator layer having a first surface being in contact with the surface and a second surface being a surface opposite to the first surface; forming a second metal layer on a part of the second surface of the first metal layer; forming a through hole penetrating between the first surface and the second surface, a part of which through hole is covered by the second metal layer, by finely processing the first insulator layer; providing the first metal layer, and a liquid layer being in contact with the first metal layer, by impregnating, in the through hole, liquid containing a liquid electrolyte; and forming, on the second surface side of the first insulator layer, a second insulator layer so as to cover the second metal layer, and the liquid layer being exposed.

Such a configuration allows not being adversely affected by the forming process of a second metal layer since a liquid layer has not been formed yet at the time of forming a second metal layer. This allows the operation characteristic of a conductive bridge memory device to improve.

The through hole can be formed by etching using a photolithography process. According to such a configuration, etching using the photolithography process is utilized, making it possible to set the position, size, shape, and density of the through hole as desired.

A third insulator layer being higher in wettability of the liquid than the first insulator layer can be formed on an inner wall of the through hole, after forming the through hole in the first insulator layer, and the liquid layer can be formed by impregnating the liquid in the through hole surrounded by the third insulator layer. Such a configuration makes it possible to easily impregnate liquid in a through hole.

The liquid can be impregnated in the through hole by supplying the liquid such that the liquid also covers the second surface of the insulator layer. Such a configuration can function as a conductive bridge memory device even when liquid also covers a second surface of an insulator layer.

A conductive bridge memory device according to one embodiment of the present disclosure comprises: a memory cell including: a first metal layer; a second metal layer; an insulator layer arranged between the first metal layer and the second metal layer, wherein the insulator layer has a first surface facing the first metal layer and a second surface facing the second metal layer and being a surface opposite to the first surface and having a communicatively connecting hole communicatively connecting between the first surface and the second surface; and a liquid layer being formed of liquid containing a liquid electrolyte impregnated in the communicatively connecting hole, wherein the liquid contains a monovalent positive ion.

One embodiment of the present disclosure makes it possible to obtain a conductive bridge memory device having a high resistance retaining characteristic.

The first metal layer or the second metal layer preferably contains Cu. Such a configuration allows easily obtaining a conductive bridge memory device having a high resistance retaining characteristic.

The monovalent positive ion preferably contains a monovalent Cu ion and/or a monovalent Ag ion. Such a configuration allows easily obtaining a conductive bridge memory device having a high resistance retaining characteristic.

A manufacturing method of a liquid electrolyte containing a monovalent Cu ion, according to one embodiment of the present disclosure, includes bringing the liquid electrolyte containing an imidazolium salt into contact with one pair of electrodes in the atmosphere not containing oxygen and applying a predetermined voltage to the one pair of electrodes, and one electrode of the one pair of electrodes is formed so as to contain Cu.

According to one embodiment of the present disclosure, the present inventors have confirmed that a liquid electrolyte containing a monovalent Cu ion could be obtained.

The predetermined voltage is preferably applied until current ceases to flow through the one pair of electrodes. According to such a configuration, it is believed that a liquid electrolyte in which a monovalent Cu ion is contained in a saturated state can be obtained.

### EXPLANATION OF LETTERS AND NUMERALS

1 CB-RAM DEVICE (SWITCHING DEVICE)
10 CB-RAM ELEMENT (SWITCHING ELEMENT)
11 FIRST METAL LAYER (ELECTRODE A)
11a FIRST SURFACE (LOWER SURFACE)
11b SECOND SURFACE (UPPER SURFACE)
111 FIRST LAYER (ELECTRODE LAYER)
112 SECOND LAYER (CAP LAYER)
12 SECOND METAL LAYER (ELECTRODE B)
12a FIRST SURFACE (LOWER SURFACE)
12b SECOND SURFACE (UPPER SURFACE)
121 FIRST LAYER (ELECTRODE LAYER)
122 SECOND LAYER (CAP LAYER)
13 INSULATOR LAYER (FIRST INSULATOR LAYER)
13h THROUGH HOLE
13a FIRST SURFACE (LOWER SURFACE)
13b SECOND SURFACE (UPPER SURFACE)
14 LIQUID LAYER
14b UPPER SURFACE
15 INSULATOR LAYER (SECOND INSULATOR LAYER)
15a LOWER SURFACE
15b UPPER SURFACE
16 INSULATOR LAYER (THIRD INSULATOR LAYER)
21 SUBSTRATE
22 CELL SELECTION TRANSISTOR
23 GATE INSULATING FILM
24, 27 INTERLAYER INSULATING FILM
25, 28 CONTACT PLUG
29 BIT LINE SELECTION TRANSISTOR
B BALLOON
E ONE PAIR OF ELECTRODES
E1 ANODE
E2 CATHODE
G GATE
S SOURCE
D DRAIN
C MEMORY CELL
Cs SELECTED MEMORY CELL
R RESIST LAYER
I INSULATOR
IL LIQUID ELECTROLYTE
M METAL
BL, BL1 to BL4 BIT LINE
WL1, WL2 WORD LINE
SL, SL1, SL2 SOURCE LINE
VB VIAL TUBE
10s SELECTED CB-RAM ELEMENT
22s SELECTED CELL SELECTION TRANSISTOR
29s SELECTED BIT LINE SELECTION TRANSISTOR

1. A conductive bridge memory device, comprising:
a memory cell including
a first metal layer;
a second metal layer;
a first insulator layer having a first surface facing the first metal layer and a second surface facing the second metal layer and being a surface opposite to the first surface, and having a through hole penetrating between the first surface and the second surface; and
a liquid layer being formed of liquid containing a liquid electrolyte impregnated in the through hole.

2. The conductive bridge memory device according to claim 1, wherein a metal constituting the second metal layer is formed of a metal being different from a metal constituting the first metal layer in electrochemical activity.

3. The conductive bridge memory device according to claim 1, wherein the through hole has a tapered shape in which a size of an opening facing the first metal layer and a size of an opening facing the second metal layer are substantially the same, or a size of either one opening is greater than a size of the other opening.

4. The conductive bridge memory device according to claim 1, wherein the through hole is a finely processed hole.

5. The conductive bridge memory device according to claim 1, wherein the through hole is formed in one to five for the memory cell.

6. The conductive bridge memory device according to claim 5, wherein the through hole is formed in one for the memory cell.

7. The conductive bridge memory device according to claim 1, wherein the liquid layer contains an ionic liquid.

8. The conductive bridge memory device according to claim 7, wherein the ionic liquid contains a mixed ionic liquid in which are mixed a solvated ionic liquid, and a low-viscosity ionic liquid being an ionic liquid having a viscosity coefficient smaller than that of the solvated ionic liquid.

9. The conductive bridge memory device according to claim 1, wherein a size of the through hole is greater than or equal to 5 nm and less than or equal to 1000 nm.

10. The conductive bridge memory device according to claim 1, wherein a shape of the through hole in planar view is a shape being closed with a straight line, a curve, or both thereof, in which shape can be drawn a circle to be included.

11. The conductive bridge memory device according to claim 1, wherein the first insulator layer is formed of an amorphous body.

12. The conductive bridge memory device according to claim 1, wherein
a part or a whole of the first metal layer is embedded in a part of the through hole; and
the liquid layer is provided in the through hole between the first metal layer embedded therein and the second metal layer.

13. The conductive bridge memory device according to claim 1, wherein
the second metal layer is formed so as to cover a part of the liquid layer; and
a second insulator layer is formed so as to cover the second metal layer, and the liquid layer not covered by the second metal layer.

14. The conductive bridge memory device according to claim 1, wherein
an inner wall of the through hole is covered with a third insulator to which a wettability of the liquid is higher than that to the first insulator layer; and
the liquid layer is provided in the through hole surrounded by the third insulator layer.

15. The conductive bridge memory device according to claim 1, wherein
the liquid layer is interposed between the second metal layer, and the second surface of the first insulator layer.

16. The conductive bridge memory device according to claim 1, wherein
the first metal layer or the second metal layer is composed of a plurality of layers;
the first metal layer or the second metal layer includes a first layer being in contact with the liquid layer of the plurality of layers and a second layer provided opposite to the liquid layer with respect to the first layer; and
the second layer functions as a cap layer to prevent oxidation of the first layer being an electrode layer to deliver and receive charges with the liquid layer.

17. The conductive bridge memory device according to claim 1, wherein
the cap layer contains at least one type of metal to be selected from a group consisting of Au, Ni, Ta, Nb, W, Pt, and Mo.

18. A switching device comprising
a switching element including
a first metal layer;
a second metal layer;
a first insulator layer having a first surface facing the first metal layer and a second surface facing the second metal layer and being a surface opposite to the first surface, and having a through hole penetrating between the first surface and the second surface; and
a liquid layer being formed of liquid containing a liquid electrolyte impregnated in the through hole, wherein
the switching device performs an electrical switching operation by electrical resistance between the first metal layer and the second metal layer changing to either a high resistance or a low resistance due to a change in voltage applied between the first metal layer and the second metal layer.

19. A manufacturing method of a conductive bridge memory device, the manufacturing method including:
forming, on a surface of a first metal layer, a first insulator layer having a first surface being in contact with the surface and a second surface being a surface opposite to the first surface;
forming a through hole penetrating between the first surface and the second surface by finely processing the first insulator layer;
providing a liquid layer being in contact with the first metal layer by impregnating, in the through hole, liquid containing a liquid electrolyte; and
forming, on the second surface side of the first insulator layer, a second metal layer being in contact with the liquid layer.

20. A manufacturing method of a conductive bridge memory device, the manufacturing method including:
forming a first insulator layer having a first surface, and a second surface being a surface opposite to the first surface;
forming a through hole penetrating between the first surface and the second surface by finely processing the first insulator layer;
embedding a first metal layer in a part in the through hole;
providing a liquid layer being in contact with the first metal layer by impregnating, in the through hole in which the first metal layer is embedded, liquid containing a liquid electrolyte; and
forming, on the second surface side of the first insulator layer, a second metal layer being in contact with the liquid layer.

21. A manufacturing method of a conductive bridge memory device, the manufacturing method including:
forming, on a surface of a first metal layer, a first insulator layer having a first surface being in contact with the surface and a second surface being a surface opposite to the first surface;
forming a second metal layer on a part of the second surface of the first metal layer;
forming a through hole penetrating between the first surface and the second surface, a part of which through hole is covered by the second metal layer, by finely processing the first insulator layer;
providing the first metal layer, and a liquid layer being in contact with the first metal layer, by impregnating, in the through hole, liquid containing a liquid electrolyte; and
forming, on the second surface side of the first insulator layer, a second insulator layer so as to cover the second metal layer, and the liquid layer being exposed.

22. The manufacturing method of a conductive bridge memory device, according to claim 19, further including:
forming the through hole by etching using a photolithography process.

23. The manufacturing method of a conductive bridge memory device, according to claim 19, further including:
after forming the through hole in the first insulator layer, forming, on an inner wall of the through hole, a third insulator layer being higher in wettability of the liquid than the first insulator layer; and
forming the liquid layer by impregnating the liquid in the through hole surrounded by the third insulator layer.

24. The manufacturing method of a conductive bridge memory device, according to claim 19, further including:
impregnating the liquid in the through hole by supplying the liquid such that the liquid also covers the second surface of the insulator layer.
